(19) United States
(12) Patent Application Publication
(10) Pub. No.: US 2026/0321548 A1
(43) Pub. Date: Oct. 15, 2026

(54) SHOWERHEAD COLD PLATES AND SUBSTRATE SUPPORTS WITH SPIRAL-SHAPED CHANNELS AND CIRCULAR MANIFOLDS

(71) Applicant: LAM RESERCH CORPORATION, Fremont, CA (US)

(72) Inventors: Spoorthi SUBRAMANYA, Bangalore (IN); Adam Christopher MACE, Morgan Hill, CA (US); Indraneel Chandrashekhar NAIK, Ratnagiri (IN); Brian Mwenze BRADLEY, San Francisco, CA (US)

(21) Appl. No.: 19/160,524

(22) PCT Filed: Mar. 4, 2024
(86) PCT No.: PCT/US2024/018305

§ 371 Date: Aug. 28, 2025

Related U.S. Application Data
(60) Provisional application No. 63/451,092, filed on Mar. 9, 2023.

(51) Int. Cl. H01J 37/32

(52) U.S. Cl. CPC H01J 37/32449; H01J 37/32522; H01J 37/32724; H01J 2237/3343

(57) ABSTRACT

A cold plate for a showerhead assembly includes: a body configured to be coupled to a showerhead of a substrate processing system; a first cooling layer including first spiral-shaped channels extending parallel to each other and azimuthally offset from each other; a first supply manifold supplying coolant to each of the first spiral-shaped channels; and a first return manifold receiving coolant from each of the first spiral-shaped channels. At least one of the first supply manifold and the first return manifold is circular shaped.

### CROSS-REFERENCE TO RELATED APPLICATIONS

This application claims the benefit of U.S. Provisional Application No. 63/451,092, filed on Mar. 9, 2023. The entire disclosure of the application referenced above is incorporated herein by reference.

### FIELD

The present disclosure relates to controlling temperature profiles of showerheads and substrate supports, and more particularly to cooling showerheads and substrate supports.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A showerhead assembly can include a faceplate that is implemented as an electrode. A gas distribution plate is disposed on the faceplate and distributes processing gas to the faceplate. A heater plate can be disposed on the gas distribution plate and heat the gas distribution plate and faceplate. A cold plate can be disposed on the heater plate and cool the gas distribution plate and faceplate.

A substrate support (e.g., a pedestal or electrostatic chuck) includes a body. Electrostatic clamping and radio frequency (RF) electrodes and a cooling channel can be disposed in the body. The cooling channel includes an inlet and an outlet. Coolant is supplied from a reservoir to the inlet and returned to the reservoir through the outlet. The cooling channel may extend laterally across the body to cool an area below a substrate supported by the substrate support.

### SUMMARY

A cold plate for a showerhead assembly is disclosed. The cold plate includes: a body configured to be coupled to a showerhead of a substrate processing system; a first cooling layer including first spiral-shaped channels extending parallel to each other and azimuthally offset from each other; a first supply manifold supplying coolant to each of the first spiral-shaped channels; and a first return manifold receiving coolant from each of the first spiral-shaped channels. At least one of the first supply manifold and the first return manifold is circular shaped.

In other features, the cold plate further includes: a second cooling layer disposed below the first cooling layer and including second spiral-shaped channels extending parallel to each other and azimuthally offset from each other; a second supply manifold supplying coolant to each of the second spiral-shaped channels; and a second return manifold receiving coolant from each of the second spiral-shaped channels. At least one of the second supply manifold and the second return manifold is circular shaped.

In other features, the cold plate further includes: a first one or more channels supplying coolant to the first supply manifold and the second supply manifold; and a second one or more channels receiving coolant from the first return manifold and the second return manifold.

In other features, the first cooling layer includes second spiral-shaped channels extending parallel to each other and azimuthally offset from each other. The second spiral-shaped channels are disposed separate from the first spiral-shaped channels.

In other features, the second spiral-shaped channels extend parallel to, are azimuthally and vertically offset from the first spiral-shaped channels, and extend from the first supply manifold to the first return manifold.

In other features, the cold plate further includes: a second supply manifold supplying coolant to each of the second spiral-shaped channels; and a second return manifold receiving coolant from each of the second spiral-shaped channels. At least one of the second supply manifold and the second return manifold is circular shaped. The second spiral-shaped channels are disposed radially outward of the first spiral-shaped channels.

In other features, the second spiral-shaped channels are wound about a same center axis as the first spiral-shaped channels.

In other features, the first cooling layer includes third spiral-shaped channels vertically offset from, extending parallel to, and in an alternating arrangement with the first spiral-shaped channels.

In other features, the second cooling layer includes fourth spiral-shaped channels vertically offset from, extending parallel to, and in an alternating arrangement with the second spiral-shaped channels.

In other features, the first cooling layer includes a bore. Some of the first spiral-shaped channels are wound at least one of toward and away from the bore and merge to form a first single channel. The first single channel is disposed around a portion of the bore.

In other features, the bore extends through the second cooling layer. Some of the second spiral-shaped channels are wound at least one of toward and away from the bore and merge to form a second single channel. The second single channel is disposed around a portion of the bore.

In other features, the cold plate further includes: a second cooling layer disposed below the first cooling layer and including third spiral-shaped channels extending parallel to each other and azimuthally offset from each other; a third supply manifold supplying coolant to each of the third spiral-shaped channels; and a third return manifold receiving coolant from each of the third spiral-shaped channels. At least one of the third supply manifold and the third return manifold is circular shaped.

In other features, the second cooling layer includes: fourth spiral-shaped channels extending parallel to each other and azimuthally offset from each other, where the fourth spiral-shaped channels are disposed separate from the third spiral-shaped channels; a fourth supply manifold supplying coolant to each of the fourth spiral-shaped channels; and a fourth return manifold receiving coolant from each of the fourth spiral-shaped channels. At least one of the fourth supply manifold and the fourth return manifold is circular shaped.

In other features, the first cooling layer includes a bore. Some of the first spiral-shaped channels are wound at least one of toward and away from the bore and merge to form a first single channel. The first single channel is disposed around a portion of the bore.

In other features, the first cooling layer includes second spiral-shaped channels vertically offset from, extending parallel to, and in an alternating arrangement with the first spiral-shaped channels.

In other features, the first cooling layer includes: a first cladding layer; a second cladding layer disposed above the first cladding layer; and a core layer disposed between the first cladding layer and the second cladding layer. The first cladding layer bonds the core layer to a first body layer of the cold plate. The second cladding layer bonds the core layer to a second body layer of the cold plate. The first spiral-shaped channels are disposed in the first cladding layer and the core layer. The second spiral-shaped channels are disposed in the second cladding layer and the core layer.

In other features, the first cooling layer includes: a first cladding layer; a second cladding layer disposed above the first cladding layer; and a core layer disposed between the first cladding layer and the second cladding layer. The first cladding layer bonds the core layer to a first body layer of the cold plate. The second cladding layer bonds the core layer to a second body layer of the cold plate. The first spiral-shaped channels are disposed in the first cladding layer, the core layer and the first body layer. The second spiral-shaped channels are disposed in the second cladding layer, the core layer and the second body layer.

In other features, the first cooling layer includes: a first cladding layer; a second cladding layer disposed above the first cladding layer; and a first body layer disposed between the first cladding layer and the second cladding layer. The first cladding layer bonds the first body layer to a first core layer of the cold plate. The second cladding layer bonds the first body layer to a second core layer of the cold plate. The first spiral-shaped channels are disposed in the first cladding layer and the first body layer. The second spiral-shaped channels are disposed in the second cladding layer and the second body layer.

In other features, the first spiral-shaped channels are at least one of in contact with and partially disposed in the first core layer. The first core layer is disposed on the first cladding layer. The second spiral-shaped channels are at least one of in contact with and partially disposed in the second core layer. The second cladding layer is disposed on the second core layer.

In other features, the first cooling layer includes: a first cladding layer; a second cladding layer disposed above the first cladding layer; and a body layer disposed between the first cladding layer and the second cladding layer. The first cladding layer bonds the body layer to a first core layer of the cold plate. The second cladding layer bonds the body layer to a second core layer of the cold plate. The first spiral-shaped channels are disposed in the body layer and are at least one of in contact with and disposed in the first cladding layer. The second spiral-shaped channels are disposed in the body layer and are at least one in contact with and disposed in the second cladding layer.

In other features, the first cooling layer includes: a first braze foil layer; a second braze foil layer disposed above the first braze foil layer; and a first body layer disposed between the first braze foil layer and the second braze foil layer. The first braze foil layer bonds the first body layer to a second body layer of the cold plate. The second braze foil layer bonds the first body layer to a third body layer of the cold plate. The first spiral-shaped channels are disposed in the first body layer and are at least one of in contact with and disposed in the first braze foil layer. The second spiral-shaped channels are disposed in the second body layer and are at least one in contact with and disposed in the second braze foil layer.

In other features, the first cooling layer includes: a first body layer; a second body layer disposed on the first body layer; and a braze foil layer disposed between bonding the second body layer to the first body layer. The first spiral-shaped channels are disposed in the second body layer and are at least one of in contact with and disposed in the braze foil layer.

In other features, the first spiral-shaped channels are mesochannels and facilitate flow of coolant from the first supply manifold to the first return manifold.

In other features, a substrate support is disclosed and includes: a body configured to support a substrate within a substrate processing system; and a cooling assembly disposed in the body. The cooling assembly includes: a first cooling layer including first spiral-shaped channels extending parallel to each other and azimuthally offset from each other; a first supply manifold supplying coolant to each of the first spiral-shaped channels; and a first return manifold receiving coolant from each of the first spiral-shaped channels. At least one of the first supply manifold and the first return manifold is circular shaped.

In other features, the cooling assembly further includes: a second cooling layer disposed below the first cooling layer and including second spiral-shaped channels extending parallel to each other and azimuthally offset from each other; a second supply manifold supplying coolant to each of the second spiral-shaped channels; and a second return manifold receiving coolant from each of the second spiral-shaped channels. At least one of the second supply manifold and the second return manifold is circular shaped.

In other features, the substrate support further includes: a first one or more channels supplying coolant to the first supply manifold and the second supply manifold; and a second one or more channels receiving coolant from the first return manifold and the second return manifold.

In other features, the first cooling layer includes second spiral-shaped channels extending parallel to each other and azimuthally offset from each other. The second spiral-shaped channels are disposed separate from the first spiral-shaped channels.

In other features, the second spiral-shaped channels extend parallel to, are azimuthally and vertically offset from the first spiral-shaped channels, and extend from the first supply manifold to the first return manifold.

In other features, the substrate support further includes: a second supply manifold supplying coolant to each of the second spiral-shaped channels. A second return manifold receives coolant from each of the second spiral-shaped channels. At least one of the second supply manifold and the second return manifold is circular shaped. The second spiral-shaped channels are disposed radially outward of the first spiral-shaped channels.

In other features, the second spiral-shaped channels are wound about a same center axis as the first spiral-shaped channels.

In other features, the first cooling layer includes third spiral-shaped channels vertically offset from, extending parallel to, and in an alternating arrangement with the first spiral-shaped channels.

In other features, the second cooling layer includes fourth spiral-shaped channels vertically offset from, extending parallel to, and in an alternating arrangement with the second spiral-shaped channels.

In other features, the first cooling layer includes a bore. Some of the first spiral-shaped channels are wound at least one of toward and away from the bore and merge to form a first single channel. The first single channel disposed around a portion of the bore.

In other features, the bore extends through the second cooling layer. Some of the second spiral-shaped channels are wound at least one of toward and away from the bore and merge to form a second single channel. The second single channel is disposed around a portion of the bore.

In other features, the substrate support further includes: a second cooling layer disposed below the first cooling layer and including third spiral-shaped channels extending parallel to each other and azimuthally offset from each other; a third supply manifold supplying coolant to each of the third spiral-shaped channels; and a third return manifold receiving coolant from each of the third spiral-shaped channels. At least one of the third supply manifold and the third return manifold is circular shaped.

In other features, the second cooling layer includes: fourth spiral-shaped channels extending parallel to each other and azimuthally offset from each other, where the fourth spiral-shaped channels are disposed separate from the third spiral-shaped channels; a fourth supply manifold supplying coolant to each of the fourth spiral-shaped channels; and a fourth return manifold receiving coolant from each of the fourth spiral-shaped channels. At least one of the fourth supply manifold and the fourth return manifold is circular shaped.

In other features, the first cooling layer includes a bore. Some of the first spiral-shaped channels are wound at least one of toward and away from the bore and merge to form a first single channel, the first single channel disposed around a portion of the bore.

In other features, the first cooling layer includes second spiral-shaped channels vertically offset from, extending parallel to, and in an alternating arrangement with the first spiral-shaped channels.

In other features, the first cooling layer includes: a first cladding layer; a second cladding layer disposed above the first cladding layer; and a core layer disposed between the first cladding layer and the second cladding layer. The first cladding layer bonds the core layer to a first body layer of the substrate support. The second cladding layer bonds the core layer to a second body layer of the substrate support. The first spiral-shaped channels are disposed in the first cladding layer and the core layer. The second spiral-shaped channels are disposed in the second cladding layer and the core layer.

In other features, the first cooling layer includes: a first cladding layer; a second cladding layer disposed above the first cladding layer; and a core layer disposed between the first cladding layer and the second cladding layer. The first cladding layer bonds the core layer to a first body layer of the substrate support. The second cladding layer bonds the core layer to a second body layer of the substrate support. The first spiral-shaped channels are disposed in the first cladding layer. The core layer and the first body layer. The second spiral-shaped channels are disposed in the second cladding layer, the core layer and the second body layer.

In other features, the first cooling layer includes: a first cladding layer; a second cladding layer disposed above the first cladding layer; and a first body layer disposed between the first cladding layer and the second cladding layer. The first cladding layer bonds the first body layer to a first core layer of the substrate support. The second cladding layer bonds the first body layer to a second core layer of the substrate support. The first spiral-shaped channels are disposed in the first cladding layer and the first body layer. The second spiral-shaped channels are disposed in the second cladding layer and the second body layer.

In other features, the first spiral-shaped channels are at least one of in contact with and partially disposed in the first core layer. The first core layer is disposed on the first cladding layer. The second spiral-shaped channels are at least one of in contact with and partially disposed in the second core layer. The second cladding layer is disposed on the second core layer.

In other features, the first cooling layer includes: a first cladding layer; a second cladding layer disposed above the first cladding layer; and a body layer disposed between the first cladding layer and the second cladding layer. The first cladding layer bonds the body layer to a first core layer of the substrate support. The second cladding layer bonds the body layer to a second core layer of the substrate support. The first spiral-shaped channels are disposed in the body layer and are at least one of in contact with and disposed in the first cladding layer. The second spiral-shaped channels are disposed in the body layer and are at least one in contact with and disposed in the second cladding layer.

In other features, the first cooling layer includes: a first braze foil layer; a second braze foil layer disposed above the first braze foil layer; and a first body layer disposed between the first braze foil layer and the second braze foil layer. The first braze foil layer bonds the first body layer to a second body layer of the substrate support. The second braze foil layer bonds the first body layer to a third body layer of the substrate support. The first spiral-shaped channels are disposed in the first body layer and are at least one of in contact with and disposed in the first braze foil layer. The second spiral-shaped channels are disposed in the second body layer and are at least one in contact with and disposed in the second braze foil layer.

In other features, the first cooling layer includes: a first body layer; a second body layer disposed on the first body layer; and a braze foil layer disposed between bonding the second body layer to the first body layer. The first spiral-shaped channels are disposed in the second body layer and are at least one of in contact with and disposed in the braze foil layer.

In other features, the first spiral-shaped channels are mesochannels and facilitate flow of coolant from the first supply manifold to the first return manifold.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example substrate processing system including a showerhead cold plate and/or a substrate support having a channel assembly in accordance with an example of the present disclosure;

FIG. 2 is a top cross-sectional view of an example mesochannel assembly;

FIG. 3 is a perspective view of a channel assembly including single-zoned layers in accordance with the present disclosure;

FIG. 4 is a top cross-sectional view of a single-zoned layer of a channel assembly in accordance with the present disclosure;

FIG. 5 is a top cross-sectional view of a dual-zoned layer of another channel assembly in accordance with the present disclosure;

FIG. 6 is a cross-sectional representative view of a cooling assembly including the dual-zoned layer of FIG. 5 in accordance with the present disclosure;

FIG. 7 is a top cross-section enlarged view of channels with offset and merged portions due to adjacent bores in accordance with the present disclosure;

FIG. 8 is a side cross-sectional enlarged view of a portion of a layered stack of a cooling assembly including cladding-core-cladding arrangements configured to include internal offset channels in accordance with the present disclosure;

FIG. 9 is a side cross-sectional enlarged view of a portion of a layered stack of a cooling assembly including cladding-core-cladding arrangements with at least portions of offset channels in accordance with the present disclosure;

FIG. 10 is a side cross-sectional enlarged view of a portion of a layered stack of a cooling assembly including cladding-metal-cladding stacks with at least portions of offset channels in accordance with the present disclosure;

FIG. 11 is a side cross-sectional enlarged view of a portion of a layered stack of a cooling assembly including body layers with at least portions of offset channels in accordance with the present disclosure;

FIG. 12 is a side cross-sectional enlarged view of a portion of a layered stack of a cooling assembly including metal-braze foil-metal stacks with offset channels in accordance with the present disclosure;

FIG. 13 is a side cross-sectional enlarged view of a portion of a layered stack of a cooling assembly including channels not vertically offset and braze foil layers for brazing adjacent body layers in accordance with the present disclosure;

FIG. 14 is a side cross-sectional enlarged view of a portion of a layered stack of a cooling assembly including a single layer of mesochannels and a braze foil layer for brazing adjacent body layers in accordance with the present disclosure; and

FIG. 15 is a side cross-sectional enlarged view of a portion of a casting including an embedded mesochannel assembly with mesochannels in accordance with the present disclosure.

In the drawings, reference numbers may be reused to identify similar and/or identical elements.

### DETAILED DESCRIPTION

In substrate processing systems, such as dielectric etch substrate processing systems, temperature profiles of a showerhead assembly and a substrate support are controlled in order to achieve a temperature profile across a substrate and a predetermined etch profile during processing of the substrate. The etch profile of the substrate is sensitive to changes in temperature. The temperature profiles are selected to satisfy critical dimension (CD) requirements and/or to maintain etch dimension uniformity for one or more features being formed during processing.

Temperatures of a substrate can be controlled actively and/or passively. A substrate processing system can include an active cooling system to adjust temperatures across a substrate during processing. The cooling system may include a temperature-controlled reservoir, a pump and coolant lines and one or more cooling channels. The cooling channels are disposed within the showerhead assembly and the substrate support. A controller controls the pump to adjust flow and temperature of coolant to and from the one or more cooling channels via the coolant lines, which adjusts a temperature of the substrate being processed. In order to passively control a temperature profile of the substrate, various structural aspects of the cooling channels may be preselected, such as dimensions, shapes, locations, layout patterns, and number of cooling channels.

An increase in RF power requirements for an etch process can result in an increase in heat load on a substrate. This requires additional cooling capacity from a showerhead assembly and a substrate support. In addition, lower substrate temperatures can provide benefits in advanced applications such as high aspect ratio etch operations. In order to provide reduced temperatures, additional thermal energy (or heat) needs to be extracted from the showerhead assembly and substrate support. This also requires additional cooling capacity of the showerhead assembly and substrate support.

The relationship between heat load W of a substrate, substrate temperature Tₛ, coolant temperature T_{fluid}, a heat transfer coefficient U, a surface area A of cooling channel, a mass flow rate m, heat capacity Cₚ, and change in coolant temperature ΔT_{fluid}, is provided by equation 1. A product of the heat transfer coefficient U and the cooling area A refers to the cooling capacity of the substrate support.

$$W = U A ( {T}_{s} - {T}_{fluid} ) = \dot{m} {C}_{p} \cdot Δ {T}_{fluid} \qquad ( 1 )$$

Equation 2 provides a similar relationship for a cooling plate (or layer) providing cooling, where Tₚₗ is temperature of the cooling plate (or layer).

$$W = U A ( {T}_{p l} - {T}_{fluid} ) = \dot{m} {C}_{p} \cdot Δ {T}_{fluid} \qquad ( 2 )$$

As heat load W increases and mass flow rate m is constant, the rise in coolant temperature ΔT_{fluid} increases. As a coolant flows through a cooling channel of the cooling plate, heat from the cooling plate is extracted and the temperature of the coolant increases. Thus, depending on the layout of the cooling channel, the cooling channel may provide a non-uniform temperature profile.

A traditional cooling channel of a showerhead cold plate and a substrate support has a single inlet and a single outlet providing limited cooling. Traditional cooling channels have rectangular-shaped cross-sections with widths and heights that are uniform along the lengths of the channels. The cross-section of a channel refers to a cross-sectional slice taken across the channel perpendicular to a length and/or longitudinal centerline of the channel, where the longitudinal centerline extends from the inlet of the channel to the outlet of the channel. The plane of the cross-sectional slice does not extend longitudinally along and/or parallel to the longitudinal centerline. The widths and heights of a traditional cooling channel are each typically greater than or equal to 6 millimeters (mm), such that each of the areas of the cross-sections is greater than or equal to 36 mm². The cooling capacity is limited by the rate at which coolant is able to be passed through the cooling channel. In order to increase cooling capacity UA, fluid flow rate can be increased. The fluid flow rate is limited by pressure drop across the cooling channel. The higher the fluid flow rate, the higher the pressure drop across the cooling channel. The fluid flow rate through the cooling channel is directly related to the pressure drop across the cooling channel. Also, in order to provide a higher pumping pressure, a larger capacity pump is needed, which increases pumping costs. Thus, velocity of fluid flow through traditional cooling channel arrangements is limited and as a result corresponding cooling capacities are also limited.

The examples set forth herein include showerhead cold plates and substrate supports with cooling assemblies. The cooling assemblies are implemented in cooling layers of the showerhead cold plates and the substrate supports. At least some of the example cooling layers include mesochannels. The channels of the cooling assemblies are spiral-shaped. Each cooling layer includes one or more zones of spiral-shaped channels, where each zone includes multiple channels extending parallel to each other and in the same direction between radially inner and radially outer circular manifolds. In some examples, adjacent ones of the channels that are implemented in the same cooling plate (or layer) are at least one i) vertically offset from each other, ii) offset from each other in a direction parallel to a center axis about which the channels are wound, and iii) offset from each other in a direction perpendicular to a plane, the plane extending parallel to centerlines of the channels, and the centerlines extending from inputs of the channels to outputs of the channels. In other examples, adjacent ones of the channels that are implemented in the same cooling layer are not at least one of i) vertically offset from each other, ii) offset from each other in a direction parallel to a center axis about which the channels are wound, and iii) offset from each other in a direction perpendicular to a plane, the plane extending parallel to centerlines of the channels, and the centerlines extending from inputs of the channels to outputs of the channels. The cooling assemblies provide increased cooling over showerhead cold plates and substrate supports having traditional cooling channels. These and other features and corresponding advantages are described below.

Each of the disclosed cooling assemblies includes one or more layers of channels, which may include mesochannels, minichannels and/or microchannels. Cross-section of the channels disclosed herein may be of various shapes. A traditional channel has a cross-section with a hydraulic diameter Dh of greater than or equal to 6 mm with a ratio of heat transfer surface area versus volume occupied by the channel of 400. A mesochannel may refer to a microchannel or a minichannel. A mesochannel may have a cross-section with a hydraulic diameter Dh of less than or equal to 3.0 mm. A minichannel may have a cross-section a hydraulic diameter Dh of less than or equal to 3.0 mm. In some embodiments, a minichannel has a cross-section with a hydraulic diameter Dh greater than 200 μm and less than or equal to 3.0 mm and a ratio of heat transfer surface area versus volume occupied by the channel of 1500-3000. A microchannel may have a cross-section with a hydraulic diameter Dh of less than or equal to 200 μm. In some embodiments, a microchannel has a cross-section with a hydraulic diameter Dh greater than 10 μm and less than or equal to 200 μm and a ratio of heat transfer surface area versus volume occupied by the channel of greater than 3000. With increase in heat transfer surface area for a same volume occupied by a channel, the same heat flux is removed with a smaller temperature differential.

In some embodiments, the cross-sections of the channels of the cooling plates (or layers) are rectangular-shaped having corresponding widths and heights. In some embodiments, the channels have cross-sections with hydraulic diameters Dh of greater than or equal to 1.5 mm and less than 6.0 mm. In some embodiments, the channels have cross-sections with hydraulic diameters Dh of less than or equal to 3.0 mm. In other embodiments, the channels have cross-sections with hydraulic diameters Dh of less than or equal to 1.0 mm.

The use of the term “micro” does not necessarily mean that the corresponding cross-sections have widths, heights, and/or hydraulic diameters that are on a micro scale (i.e., less than 1 mm). However, the microchannels may have cross-sections with widths, heights and cross-sections that are each less than 1 mm. Each of the channels disclosed herein performs as a heat exchanger by extracting thermal energy from the body of the corresponding cooling assembly and transfers the thermal energy to a coolant in the channels.

The microchannels have high heat transfer coefficients (e.g., three to four times higher than conventional channels) and have a high surface to volume ratio. Microchannels are suited for applications requiring a compact design. The small cross-sectional profiles of the microchannels provide design versatility because the microchannels may be incorporated in different plates and/or portions of a body of a showerhead cold plate and/or a substrate support to provide different temperature profiles.

Each of the showerhead cold plates and substrate supports disclosed herein may include one or more pairs of manifolds, where each pair of manifolds includes a supply manifold and a return manifold. Each pair of manifolds is connected to a respective set of channels. Each pair of manifolds and corresponding set of channels are fluidically connected to perform as a single heat exchanger. Each of the heat exchangers include channels that are connected in parallel between a same pair of manifolds such that there are two or more parallel paths. This is unlike conventional channels, which do not extend between manifolds and are standalone single channels having a single path for fluid flow with a respective input and output. For example, a conventional substrate support typically includes only one conventional channel.

Some of the examples minimize temperature variations laterally across a showerhead and/or substrate support. This includes minimizing variations point-to-point. The disclosed examples include channel assemblies, which minimize temperatures of cooling fluid while either i) maintaining the cooling fluid at nearly uniform temperatures across each zone of a cooling plate (or layer), and/or ii) maintaining the cooling fluid at nearly uniform temperatures across a cooling plate (or layer).

There is an ever increasing trend for more power in dielectric tools, for example, an increase from 16 kilowatts to 25 kilowatts. With increased power comes increased cooling requirements. Thus, the cooling capacities of showerhead cold plates and substrate supports in order to maintain the showerhead and the substrate support at set temperatures is increased. As an example, a substrate processing system may have a temperature requirement for a showerhead of 100-150° C.

In order to extract additional heat using a traditional showerhead cold plate, flow rate of coolant through a channel of the cold plate and/or increased heat transfer surface area is needed. This can increase a coolant supply pressure requirement beyond an existing chiller capacity. It is not feasible to package one or more larger channels in the confined space of a showerhead cold plate in order to increase heat transfer surface area of the channel(s) of the showerhead cold plate.

In order to increase supply pressure of coolant, additional components (e.g., valves, etc.) are needed with additional system complexity and costs. A chiller with increased output pressure is also needed. In addition, coolant circuit components a larger and thus occupy more space.

The examples set forth herein provide multi-layered cooling assemblies with parallel channel arrangements occupying the same space as traditional cooling assemblies but with increased heat transfer surface area. The increased amount of heat transfer surface area, may be, for example, 4-5 times as much as a traditional cooling assembly. Coolant flowrate of the multi-layered cooling assemblies is able to be increased with a same drop in pressure across channels of the cooling assemblies as compared to a traditional cooling assembly. As a result, lower cooling plate temperatures are achieved with the same amount of heat load. The increased cooling is provided without requiring increased volume for the cooling assemblies. The cooling assemblies provide improved temperature distribution uniformity across cooling plates and layers.

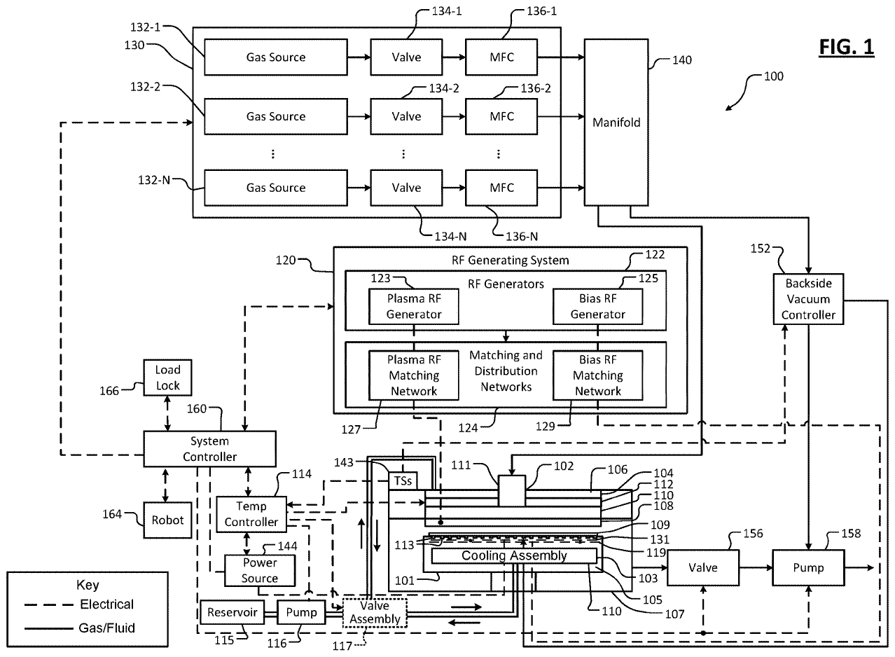

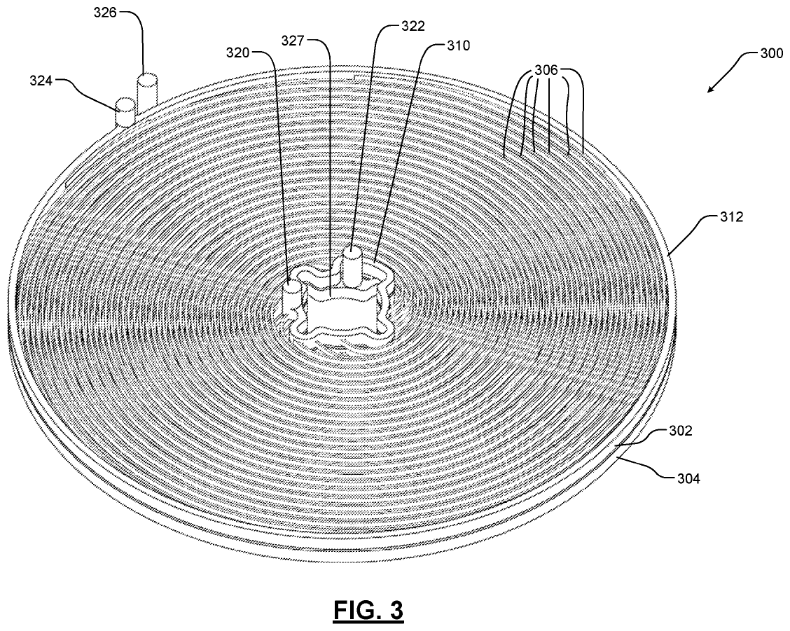

FIG. 1 shows an example substrate processing system 100 including a substrate support 101, shown as an electrostatic chuck, and a showerhead assembly 102. The substrate support 101 includes a cooling assembly 103 and the showerhead assembly 102 includes a cold (or cooling) plate 104. The cooling assembly 103 and/or the cold plate 104 may include or be replaced with any of the cooling assemblies disclosed herein, examples of which and portions thereof are shown in a described with respect to FIGS. 3-13. The cooling assembly 103 and the cold plate 104 may include any of the features shown in FIGS. 3-13.

Although FIG. 1 shows a capacitive coupled plasma (CCP) system, the embodiments disclosed herein are applicable to transformer coupled plasma (TCP) systems, inductively coupled plasma (ICP) systems and/or other processing systems and plasma sources that include a substrate support. The embodiments are applicable to dry etch processing systems and other processing systems including a showerhead and/or a substrate support. In the example shown, the substrate support 101 includes a body 105. The body 105 may be formed of different materials and/or different ceramic compositions. The body 105 may include, for example, aluminum, aluminum alloy, aluminum nitride (AlN₃), aluminum oxide (Al₂O₃), and/or aluminum oxynitride (AlON). The cold plate 104 includes a body 106 that may be formed of aluminum, aluminum alloy, aluminum nitride (AlN₃), aluminum oxide (Al₂O₃), and/or aluminum oxynitride (AlON).

The substrate processing system 100 includes a processing chamber 107. The substrate support 101 is enclosed within the processing chamber 107. The processing chamber 107 also encloses other components, such as an upper electrode (or showerhead faceplate) 108, and contains RF plasma. During operation, a substrate 109 is arranged on and electrostatically clamped to the substrate support 101.

The showerhead assembly 102 includes a gas distribution plate 110 that introduces and distributes gases via the showerhead faceplate 108. The showerhead assembly 102 further includes a stem portion 111 including one end connected to a top surface of the processing chamber 107. The gas distribution plate 110 and the showerhead faceplate 108 are collectively cylindrical-shaped and may be referred to as the showerhead. The gas distribution plate 110 and the showerhead faceplate 108 extend radially outward at a location that is at an opposite end of the stem portion 111 as the top surface of the processing chamber 107. A substrate-facing surface of the showerhead faceplate 108 includes holes through which process or purge gas flows. The showerhead assembly 102 may include a heat plate 112 disposed on the gas distribution plate 110. The cold plate 104 may be disposed on the heat plate 112. Although the cold plate 104 is shown disposed on the heat plate 112, the heat plate 112 may not be included and the cold plate 104 may be disposed on the gas distribution plate 110.

In an embodiment, the substrate support 101 may include one or more gas channels 113 for flowing backside gas to a backside of the substrate 109. The substrate support 101 may include the cooling assembly 103, which receives coolant from a pump 116. The cold plate 104 may also receive coolant from the pump 116.

A temperature controller 114 controls operation of the pump 116 to control flow and temperature of coolant to and from the cooling assembly 103 and the cold plate 104. The pump 116 may circulate coolant between i) a reservoir 115 and ii) the cooling assembly 103 and the cold plate 104. Although a single pump 116 is shown, two or more pumps may be included. In one embodiment, each of the cooling assembly 103 and the cold plate 104 includes a single coolant input and a single coolant output. In other embodiments, each of the cooling assembly 103 and the cold plate 104 includes multiple coolant inputs and coolant outputs. A valve assembly 117 may be disposed between the pump 116 and the cooling assembly 103 and the cold plate 104 and be controlled by the temperature controller 114. Pairs of supply and return lines may be connected (i) between the one or more pumps and the cooling assembly 103 and the cold plate 104, and/or (ii) between the valve assembly 117 and the cooling assembly 103 and the cold plate 104.

An RF generating system 120 generates and outputs RF voltages to the upper electrode 108 and one or more lower electrodes 119 in the substrate support 101. One of the upper electrode 108 and the substrate support 101 may be DC grounded, AC grounded or at a floating potential. For example only, the RF generating system 120 may include one or more RF generators 122 (e.g., a capacitive coupled plasma RF power generator, a bias RF power generator, and/or other RF power generator) that generate RF voltages, which are fed by one or more matching and distribution networks 124 to the upper electrode 108 and/or the substrate support 101. An electrode that receives an RF signal, an RF voltage and/or RF power is referred to as a RF electrode. As an example, a plasma RF generator 123, a bias RF generator 125, a plasma RF matching network 127 and a bias RF matching network 129 are shown. The plasma RF generator 123 may be a high-power RF generator producing, for example, 6-10 kilo-watts (KW) of power or more. The bias RF matching network supplies power to RF electrodes, such as RF electrodes 119.

A gas delivery system 130 includes one or more gas sources 132-1, 132-2, . . . , and 132-N (collectively gas sources 132), where N is an integer greater than zero. The gas sources 132 supply one or more precursors and gas mixtures thereof. The gas sources 132 may also supply etch gas, carrier gas and/or purge gas. Vaporized precursor may also be used. The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. An output of the manifold 140 is fed to the processing chamber 107. For example only, the output of the manifold 140 is fed to the showerhead.

Although shown separately from a system controller 160, the temperature controller 114 may be implemented as part of the system controller 160. The substrate support 101, the cooling assembly 103, the gas distribution plate 110, and/or the cold plate 104 may include multiple temperature controlled zones, where each of the zones includes a temperature sensor and a set of channels. The temperature controller 114 may monitor temperatures as indicated by the temperature sensors and adjust flow rate and/or temperature of coolant circulating through the one or more sets of channels to adjust the temperatures to target temperatures. The temperatures sensors and other temperatures sensors are represented by temperature sensors 143. Although the temperature sensors 143 are shown as being connected to the processing chamber 107, at least some of the temperature sensors 143 are located within the processing chamber 107. The temperature sensors 143 may include resistive temperature devices, thermocouples, digital temperature sensors, and/or other suitable temperature sensors.

The substrate processing system 100 may also include a power source 144 that provides power, including a high voltage, to clamping electrodes 131 to electrostatically clamp the substrate 109 to the substrate support 101. Clamping electrodes receive power to electrostatically clamp down the substrate 109 to the substrate support 101 and may receive RF signals, RF voltages and/or RF power. The power source 144 may be controlled by the system controller 160.

The substrate processing system 100 may further include a backside vacuum controller 152. The backside vacuum controller 152 may receive gas from the manifold 140 and supply the gas to channels 113 and/or to a pump 158. This improves transfer of thermal energy between the substrate support 101 and the substrate 109. The backside gas may also be provided to improve substrate peripheral edge purging and vacuum tracking of a location of the substrate. The channels 113 may be fed by one or more injection ports. In one embodiment, multiple injection ports are included for improved cooling. As an example, the backside gas may include helium.

The temperature controller 114 may control operation of the pump 116 and/or other coolant circulating pumps and/or the valve assembly 117 based on detected parameters from ones of the temperature sensors 143 within the processing chamber 107. The backside vacuum controller 152 controls flow rate of backside gas (e.g., helium) to the channels 113 for cooling the substrate 109 by controlling flow from one or more of the gas sources 132 to the channels 113. The backside vacuum controller 152 controls pressure and flow rates of gas supplied to channels 113 based on detected parameters from the temperature sensors 143. In one embodiment, the temperature controller 114 and the backside vacuum controller 152 are implemented as a combined single controller. During a deposition process, the substrate 109 may be heated in presence of high-power plasma. Flow of gas through the gas channels 113 may reduce temperatures of the substrate 109.

A valve 156 and the pump 158 may be used to evacuate reactants from the processing chamber 107. The system controller 160 may control components of the substrate processing system 100 including controlling supplied RF power levels, pressures and flow rates of supplied gases, RF matching, etc. The system controller 160 controls states of the valve 156 and the pump 158. A robot 164 may be used to deliver substrates onto, and remove substrates from, the substrate support 101. For example, the robot 164 may transfer substrates between the substrate support 101 and a load lock 166. The robot 164 may be controlled by the system controller 160. The system controller 160 may control operation of the load lock 166.

The valves, gas pumps, power sources, RF generators, etc. referred to herein may be referred to as actuators. The microchannels, gas channels, etc. referred to herein may be referred to as temperature adjusting elements.

The substrate support 101 and the cold plate 104 may each have a stacked structure with multiple plates and/or layers as further described below. As an example, the substrate support 101 and/or the cold plate 104 may each include multiple plates and/or layers including one or more channel layers, one or more crossover layers, manifold layers, intermediate layers, etc. Manifolds may be implemented in the same or different layers as the channels. Makeup and materials of the layers are further described below.

In the example shown, the electrodes 119, 131 are disposed in uppermost ones of the layers of the substrate support 101. The cooling assembly 103 is disposed in another one or more of the layers. Although a single cooling assembly is shown, the body 105 may include any number of cooling and/or channel assemblies disposed in any number of channel layers, where each layer may include any number of channels having various sizes, shapes, layout patterns, and dimensions.

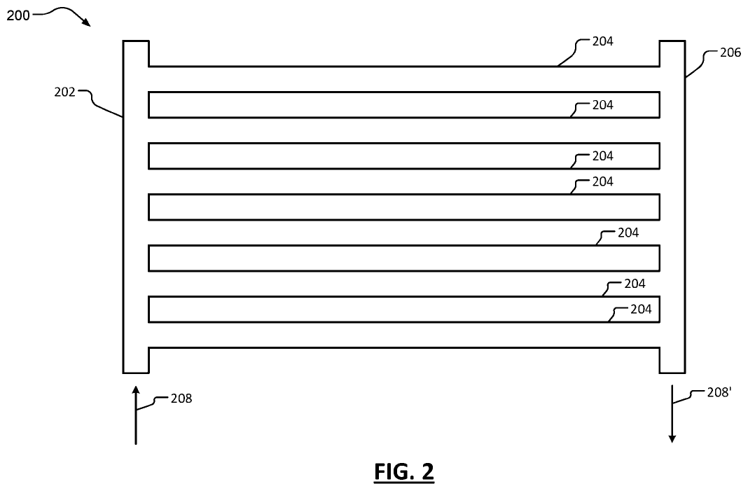

FIG. 2 shows a channel assembly 200 that includes a supply (or input) manifold 202, channels 204 and a return (or output) manifold 206. The supply manifold 202 receives coolant 208. The coolant 208 passes through the supply manifold 202 to the channels 204 and then to the return manifold 206. The channels 204 may extend in a parallel arrangement, as shown. The output of the return manifold is coolant 208′, which is at an increased temperature as compared to the received coolant 208. The channels 204 facilitate flow of coolant from the supply manifold 202 to the return manifold 206.

The example of FIG. 2 is a simplified representation. The examples of FIGS. 3-6 include channel assemblies with multiple layers. Each layer includes channels that are spiral-shaped, wound in a parallel arrangement and having i) inputs that are azimuthally offset from each other, and ii) outputs that are azimuthally offset from each other. The inputs are connected to a first manifold and the outputs are connected to a second manifold. The manifolds may be annular (or ring) shaped and/or irregularly shaped to minimize space.

The manifolds disclosed herein may be in different locations and away from each other as shown or may be disposed in a close arrangement when there are multiple zones, where for example manifolds of different zones are near each other. The manifolds may be disposed to provide a center hot or edge hot arrangement. The phrase “center hot” refers to a center and/or radially inward annular region of a substrate support, cold plate, cooling plate, cooling layer, etc. The phrase “edge hot” refers to an outer circumferential edge and/or radially outward annular region of a substrate support, cold plate, cooling plate, cooling layer, etc.

The channels disclosed herein may be implemented as mesochannels, which provide increased surface area for extracting thermal energy from surrounding material. By providing an increased number of smaller channels, the mesochannels collectively have more external channel surface area than a signal traditional channel. The thermal energy is transferred to coolant in the mesochannels and passed through the mesochannels. The mesochannels have a higher surface to volume ratio and an increased heat transfer coefficient U, as compared to traditional cooling channels. By providing an increased number of channels, there is an increased number of channel sides, which corresponds to an increased amount of surface area. The sum of the surface areas of the sides of the mesochannels is more than that of a traditional channel. Although the collective volume of the mesochannels may be less than the volume of a single traditional channel, the mesochannels have increased surface area and provide the same or more cooling than a traditional channel. The collective surface area to volume ratio of the mesochannels is much higher than a traditional channel. The heat transfer coefficient U is a function of fluid flow velocity. The smaller the cross-sectional area of the channel, generally the higher the velocity of coolant passing through the channel. Since the mesochannels have a small cross-sectional area, the velocity of fluid flow is increased and thus the heat transfer coefficient is increased. The heat transfer coefficient U of the corresponding mesochannel assembly may be, for example, twice that of a conventional cooling channel assembly. The mesochannels provide increased cooling capacity UA while exhibiting similar fluid pressure drops between inputs and outputs of the mesochannels. Depending on the design, the pressure drops may be slightly higher or slightly lower than traditional cooling channels.

If the same heat load is provided using a conventional cooling channel as provided using a mesochannel assembly, then the driving temperature differential between the substrate support and the fluid for the mesochannel assembly is much less than the temperature differential of the conventional cooling channel to achieve the same substrate temperatures. The mesochannels may provide 2-3 times more heat transfer than a conventional cooling channel arrangement. This allows fluid inlet temperature for a mesochannel to be much higher than for conventional channels, for the same substrate temperature. A conventional channel requires fluid temperature to be as low as −60° C. to −100° C. for certain processes. With a mesochannel, this coolant temperature may be brought up to −30° C. to −70° C., greatly reducing the need of cryogenic temperature control at the pump end. The capacity of the pump is greater than a predetermined minimum capacity to assure that the flow rate is greater than a predetermined minimum flow rate to prevent coolant temperatures from exceeding predetermined maximum temperatures. If the flow rate is too slow, then the temperatures across the substrate support can exceed set maximum temperature thresholds.

The mesochannels disclosed herein may operate in a single-phase mode or in a dual-phase mode. The single-phase mode refers to when the coolant flowing through the mesochannels remains in a liquid state. The dual-phase mode refers to when the coolant flowing through the mesochannels changes between a liquid state and a gas state. Latent heat occurs when the coolant transitions between liquid and gas states. Mesochannels have approximately 70% less volume for a same amount of heat load as conventional cooling channels. The heat transfer coefficient U may increase 100% without boiling as compared to a conventional channel. The heat transfer coefficient U may increase greater than 300% with boiling as compared to a conventional channel.

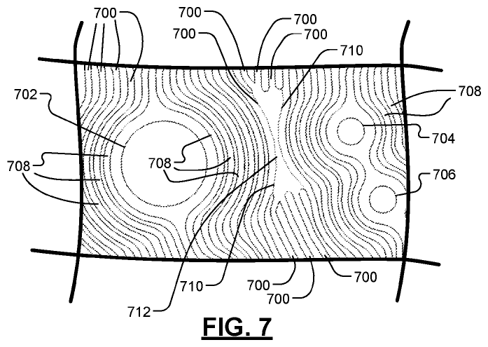

As described above, the cross-sections of the mesochannels are small (e.g., hydraulic diameter Dh of less than 3.0 mm), which provides a structure with design versatility. As an example, a width or height may be less than or equal to 4 mm when the hydraulic diameter Dh is 2.0 mm. Mesochannel assemblies may be incorporated in a substrate support, a cold plate and/or portions thereof in various arrangements. The mesochannel assemblies may be located in various locations and in one or more layers while allowing space for other components. In one embodiment, a first plate is machined to form mesochannel grooves (three sides of the microchannels) and a second plate is attached to the first plate and provides the fourth sides of the mesochannels. Vacuum brazing may be implemented to join the second plate to the first plate. The second plate may be sealed and/or bonded to the first plate. In another embodiment, the mesochannels are formed using additive manufacturing techniques. In addition to brazing, three-dimensional (3D) printing may be implemented to form at least portions of the mesochannel assemblies disclosed herein. Other examples are shown and described with respect to FIGS. 7-13.

The channels in the following examples may have various sizes and cross-sectional shape and areas and thus exhibit different flow velocities and pressures. Flow per channel q is equal to a product of a cross-sectional area of the channel A_{c} and flow velocity v. In an embodiment, the channels are sized and shaped such that the flow velocity of each of the channels is less than 2.5 meters per second (m/s) to avoid erosion of the channel.

FIG. 3 shows a channel assembly 300 including layers 302, 304. Each of the layers 302, 304 has a single respective cooling zone with a respective set of channels. The first layer 302 includes first channels 306 and the second layer includes second channels (not shown in FIG. 3). The second channels may be configured similarly as the first channels 306. In an embodiment, the channels of the layers 302, 304 are implemented as mesochannels. The layer 302 includes a first manifold 310 and a second manifold 312. The layer 304 includes a third manifold and a fourth manifold (not shown in FIG. 3. The third manifold and the fourth manifold may be configured similarly as the first manifold 310 and the second manifold 312. One of the first manifold 310 and the second manifold 312 is an input (or supply) manifold and the other manifold is an output (or return) manifold. The manifolds of the layers 302, 304 are connected respectively to first channels 320, 322 and second channels 324, 326. In an embodiment, the manifold 310 is shaped to minimize space and is routed around mounting hole locations, a central bore 327, and the channels 320, 322. The central bore 327 may be used to supply process gas to a showerhead.

In an embodiment, the first channels 320, 322 are implemented as input (or supply) channels and the second channels 324, 326 are implemented as output (or return) channels. In another embodiment, the first channels 320, 322 are implemented as output channels and the second channels 324, 326 are implemented as input channels. In yet another embodiment, the channels 320, 326 are implemented as input channels and the channels 322, 324 are implemented as output channels. In another embodiment, the channels 322, 324 are implemented as input channels and the channels 320, 326 are implemented as output channels.

In one embodiment, the layers 302, 304 are implemented as layers of a body of a substrate support or a cold plate of a showerhead assembly. In another embodiment, the layer 302 is implemented as a cooling plate that is stacked on layer 304, which is implemented as another cooling plate.

The channels of each of the layers 302, 304 are spiral-shaped, wound in parallel, are equally spaced apart from each other, have inputs azimuthally offset from each other, and have outputs azimuthally offset from each other. In an embodiment, the channels may be the same length. The channels of each of the layers 302, 304 have a first end that is fluidically coupled to one of the radially inner manifolds (e.g., the manifold 310) and a second end fluidically coupled to one of the radially outer manifolds (e.g., the manifold 312). By being circular, the manifolds 310, 312 and other manifolds disclosed herein uniformly distribute and return coolant for improved temperature uniformity 360° about the corresponding cooling assemblies and corresponding cooling layers and/or plates.

Each of the sets of channels of the layers 302, 304 and each of the other sets of channels disclosed herein are wound in a same direction (e.g., clockwise or counterclockwise) about a same center axis.

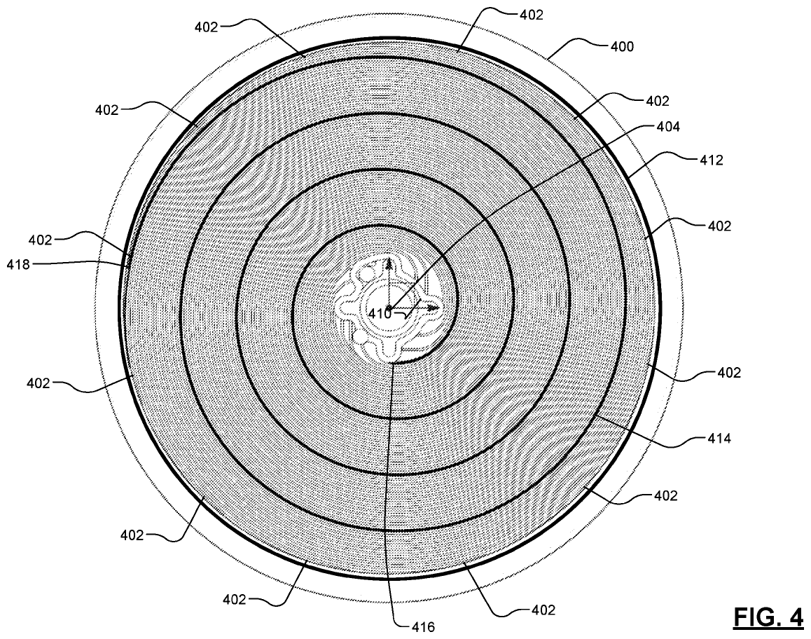

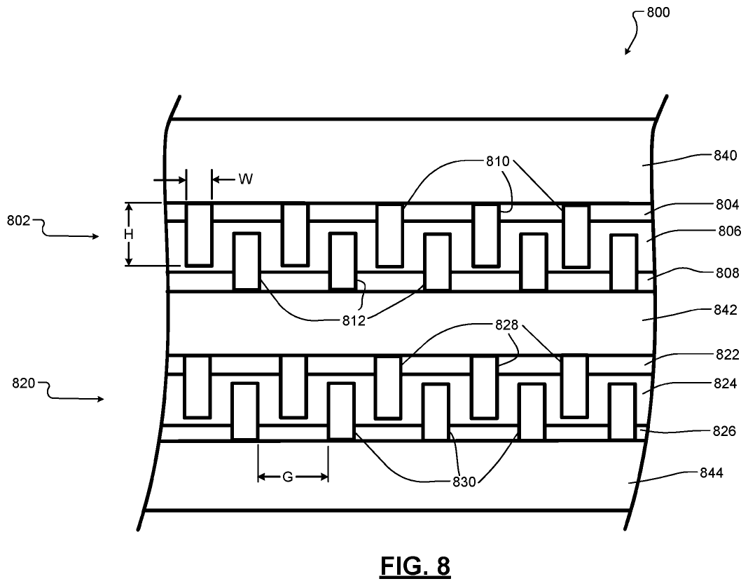

FIG. 4 shows a single-zoned layer 400 of a channel assembly. The layer 400 includes a single set of channels 402 that are spiral-shaped, wound in parallel, are spaced apart from each other, have inputs azimuthally offset from each other, and have outputs azimuthally offset and equal distance apart from each other. The channels 402 are wound about a centerline, represented by point 404, of the layer 400. In an embodiment, the channels 402 have the same length. The channels 402 have first ends that are fluidically coupled to a radially inner manifold 410 and second ends fluidically coupled to a radially outer manifold, represented by circle 412. A spiral 414 is shown as a representation of one of the channels 402 and has a first end 416 and a second end 418. The spiral 414 does not precisely follow the path of one of the channels 402 but rather is provided as a representation of one of the channels 402 and illustrates the general shape of each of the channels 402. The first end 416 or the second end 418 may be implemented as an input and the other one of the ends is implemented as an output. The layer 400 may be configured as shown in FIG. 7 and/or as one or more layers of any of FIGS. 8-13.

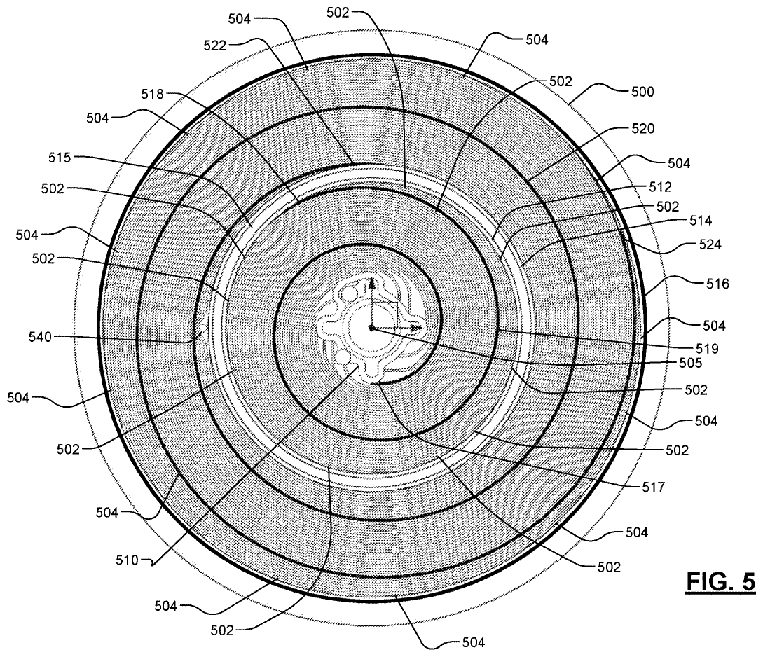

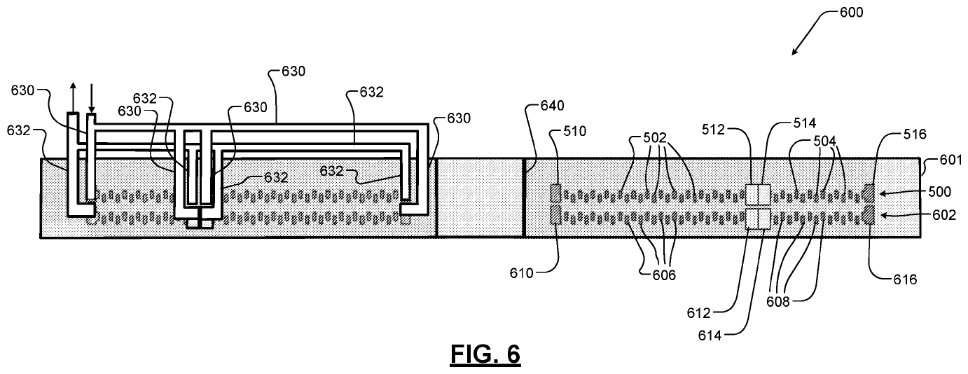

FIG. 5 shows a dual-zoned layer 500 of another channel assembly (e.g., the channel assembly 600 of FIG. 6). The layer 500 includes two zones having respective sets of channels 502, 504. Lead lines of numerical designators 502 are touching end portions of the channels 502. The channels 504 are radially outward from the channels 502. Temperatures of the first and second zones may be independently controlled and provide different amounts of cooling. As an example, more cooling may be provided in the first zone, which may be radially inward of the second zone. This may occur, for example, when the dual-zoned layer 500 is implemented in a cooling assembly of a cold plate used for cooling a showerhead. As another example, more cooling may be provided in the second zone, which may be radially outward of the first zone. The channels 502, 504 are wound about a centerline, represented by point 505, of the layer 500.

The channels 502 are spiral-shaped, wound in parallel, are spaced equally apart from each other, have inputs azimuthally offset from each other, and have outputs azimuthally offset and equally distanced apart from each other. The channels 504 are spiral-shaped, wound in parallel, are equally spaced apart from each other, have inputs azimuthally offset from each other, and have outputs azimuthally offset and equally distanced apart from each other. In an embodiment, the channels 502 have the same length. In an embodiment, the channels 504 have the same length. The channels 502 may have the same or different length than the channels 504. The channels 502 may have the same cross-sectional area, which may be consistent from the inputs of the channels 502 to the outputs of the channels 502. The channels 504 may have the same cross-sectional area, which may be consistent from the inputs of the channels 504 to the outputs of the channels 504. The channels 502 may have the same or different cross-sectional area than the channels 504.

The number of channels per zone may be directly related to a flow percentage of coolant to each of the zones. This affects the heat transfer coefficients of the zones. The number of channels may be set based on pressure drop and/or flow rate requirements for each of the zones for the application of use.

The channels 502 have first ends that are fluidically coupled to a radially inner manifold 510 and second ends fluidically coupled to a radially outer manifold, represented by circle 512. The channels 504 have first ends that are fluidically coupled to a radially inner manifold, represented by circle 514, and second ends fluidically coupled to a radially outer manifold, represented by circle 516. The manifolds 512, 514 are disposed at inner and outer peripheries of an annular region 515, which is radially between the zones of the channels 502, 504. The annular region 515 is void of channels and separates the channels 502, 504.

A spiral 519 is shown as a representation of one of the channels 502 and has a first end 517 and a second end 518. A spiral 520 is shown as a representation of one of the channels 504 and has a first end 522 and a second end 524. The spirals 519, 520 do not precisely follow the paths of two of the channels 502, 504 but rather are provided as representations respectively of one of the channels 502 and one of the channels 504 and illustrate the general shape of each of the channels 502, 504. The first end 516 or the second end 518 may be implemented as an input and the other one of the ends is implemented as an output. The first end 522 or the second end 524 may be implemented as an input and the other one of the ends is implemented as an output. The manifolds 510, 512, 514, 516 are circular shaped for improved azimuthal temperature uniformity.

FIG. 6 shows a channel assembly 600 including a body 601 with the dual-zoned layer 500 of FIG. 5, another dual-zoned layer 602 configured similarly as the dual-zoned layer 500, and corresponding supply channels and return channels. The layer 500 includes the channels 502, 504 and the manifolds 510, 512, 514, 516. The channels 502, 504 extend parallel to each other, are azimuthally offset from each other, and are equally spaced apart from each other. The layer 602 includes channels 606, 608 and manifolds 610, 612, 614, 616. The channels 606, 608 are configured similarly as the channels 502, 504. The channels 606, 608 extend parallel to each other, are azimuthally offset from each other, and are equally spaced apart from each other. In one embodiment, the channels 606, 608 have a same pattern as the channels 502, 504 and are disposed below and are laterally aligned with the channels 502, 504. The manifolds 610, 612, 614, 616 are configured similarly as the manifolds 510, 512, 514, 516.

The layer 500 also includes one or more bores (one example bore 540 is shown. The bores may be for passage of, for example, lift pins, sensors, probes, electrodes, etc. A portion of nearby channels such as, for example, portions of selected ones of the channels 504 are offset and/or merged together to provide space for the bores (e.g., the bore 540). This is further illustrated and described with respect to FIG. 7.

As an example, channels 630 may be fluidically coupled to the manifolds 510, 514, 612 and 616. Channels 632 may be fluidically coupled to the manifolds 512, 516, 610 and 614. In one embodiment, the channels 630 are inlet channels and the channels 632 are outlet channels, as shown. In another embodiment, the channels 630 are outlet channels and the channels 632 are inlet channels. Other inlet and outlet channel arrangements may be implemented, where any of the manifolds 510, 512, 514, 516 and manifolds 610, 612, 614, 616 are supply or return manifolds. Although the manifolds 510, 512, 514, 516, 610, 612, 614, 616 are shown in the same layers as the corresponding channels 502, 504, 606, 608, the manifolds 510, 512, 514, 516, 610, 612, 614, 616 may be in different layers than the channels 502, 504, 606, 608. Although portions of the channels 630, 632 are shown outside of the body 601, all of the channels 630, 632 may be disposed in one or more layers of the body 601.

The layers 500, 602 may be configured as described below with respect to any of FIGS. 7-13. The body 601 includes a central bore 640. The central bore 640 may be used for supplying process gas when the cooling assembly is implemented as part of a cold plate of a top plate and/or showerhead assembly. The central bore 640 may be used for passage of electrical lines for electrodes and/or sensors and/or for supplying backside gas when the cooling assembly is implemented as part of a substrate support.

FIG. 7 shows channels (some of which are designated 700) with offset and merged portions due to adjacent bores. Bores 702, 704, 706 are shown as examples. Example offset portions are shown (some of which are designated 708). The offset portions are disposed around portions of the bores 702, 704, 706. The offset portions are routed around and do not follow normal spiral paths, which may extend through locations of the bores 702, 704, 706. The offset portions are provided to assure that fluid within the corresponding channels does not leak into the bores 702, 704, 706. Example merged portions (or manifolds) 710 are shown with a single channel 712 connecting the merged portions. The single channel 712 may have a minimum cross-sectional area equal to a sum of the cross-sectional areas of the corresponding merged channels. As an example, a minimum cross-section of the channel 712 may be equal to a sum of the cross-sectional areas of the three channels merged into the channel 712.

In the following FIGS. 8-15, various cladding layers, core layers and body layers are shown. Each of the cladding layers may be implemented as braze foil layers that may be melted during a brazing process (e.g., vacuum brazing) to bond layers adjacent to the cladding layers. The core layers do not melt during the brazing process. The body layers may also not melt during the brazing process.

FIG. 8 shows a portion 800 of a layered stack of a cooling assembly including cladding-core-cladding arrangements with internal offset channels. The cooling assembly includes a first cooling layer 802 including a first cladding layer 804, a first core layer 806, a second cladding layer 808, a first set of channels 810 and a second set of channels 812. The first set of channels 810 may extend vertically through the first cladding layer 804 and vertically into the first core layer 806. The second set of channels 812 are vertically offset from the first set of channels 810, may extend vertically and partially into the first core layer 806, and may extend through the second cladding layer 808.

The cooling assembly further includes a second cooling layer 820 including a third cladding layer 822, a second core layer 824, a fourth cladding layer 826, a third set of channels 828 and a fourth set of channels 830. The third set of channels 828 may extend through the third cladding layer 822 and partially into the second core layer 824. The fourth set of channels 830 are vertically offset from the third set of channels 828, may extend vertically and partially into the second core layer 824, and may extend through the fourth cladding layer 826. The third set of channels 828 may be radially aligned with the first set of channels 810. The fourth set of channels 830 may be radially aligned with the second set of channels 812.

The layers 804, 806, 808 are disposed between body layers 840, 842. The layers 822, 824, 826 are disposed between body layers 842, 844. In an embodiment, the body layers 840, 842, 844 are implemented as metal layers. As an example, the cladding layers 804, 808, 822, 826 may be formed of aluminum cladding material, the core layers 806, 824 may be formed of an aluminum alloy, and the body layers 840, 842, 844 may be formed of aluminum. In the example of FIG. 8, the channels 810, 812, 828, 830 are machined in the cladding layers 804, 808, 822, 826 and core layers 806, 824. As an example, the width W of each of the channels 810, 812, 828, 830 and/or other channels disclosed herein may be 1.5-2.0 millimeters (mm) and the height H of each of the channels 810, 812, 828, 830 and/or other channels disclosed herein may be 3.0-5.0 mm. The core layers 806, 824 may be brazed to the body layers 840, 842, 844 by melting the cladding layers 804, 808, 822, 826. The melting of the cladding layers 804, 808, 822, 826 does not fill the channels 810, 812, 828, 830.

The first set of channels 810 are alternatively disposed in a radial direction relative to the second set of channels 812. The third set of channels 828 are alternatively disposed in a radial direction relative to the fourth set of channels 830. Although the channels 810 are shown vertically offset from the channels 812, the channels 810 may not be vertically offset from the channels 812. The channels 810 are vertically offset from the channels 812 to provide gaps (or bridge joints) radially between channels along a same cladding layer for brazing. An example gap G is shown. The gap G between channels is provided to assure that wall thicknesses are not too thin for brazing and brazed areas have set minimal sizes.

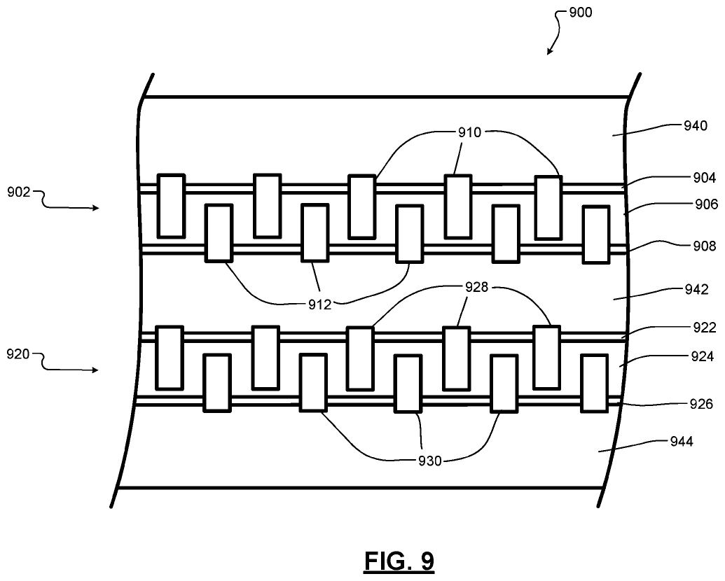

FIG. 9 shows a portion 900 of a layered stack of a cooling assembly including cladding-core-cladding arrangements with portions of offset channels. The cooling assembly includes a first cooling layer 902 including a first cladding layer 904, a first core layer 906, a second cladding layer 908, a first set of channels 910 and a second set of channels 912. The first set of channels 910 are arranged partially in the first cladding layer 904, extend through the first core layer 906, and extend vertically into the body layer 940. The second set of channels 912 are vertically offset from the first set of channels 910, arranged partially in the first core layer 906, extend through the second cladding layer 908, and extend vertically into the body layer 942.

The cooling assembly further includes a second cooling layer 920 including a third cladding layer 922, a second core layer 924, a fourth cladding layer 926, a third set of channels 928 and a fourth set of channels 930. The third set of channels 928 are arranged partially in the third cladding layer 922, extend through the second core layer 924, and extend vertically into the body layer 942. The fourth set of channels 930 are vertically offset from the third set of channels 928 and arranged partially in the second core layer 924, extend through the fourth sublayer layer 926, and extend vertically into the body layer 944. The third set of channels 928 may be radially aligned with the first set of channels 910. The fourth set of channels 930 may be radially aligned with the second set of channels 912.

The layers 904, 906, 908 are disposed between body layers 940, 942. The layers 922, 924, 926 are disposed between body layers 942, 944. In an embodiment, the body layers 940, 942, 944 are implemented as metal layers. As an example, the cladding layers 904, 908, 922, 926 may be formed of aluminum cladding material, the core layers 906, 924 may be formed of an aluminum alloy, and the body layers 940, 942, 944 may be formed of aluminum. In the example of FIG. 9, the channels 910, 912, 928, 930 are machined in the cladding layers 904, 908, 922, 926 and core layers 906, 924. The core layers 906, 924 may be brazed to the body layers 940, 942, 944 by melting the cladding layers 904, 908, 922, 926. The melting of the cladding layers 904, 908, 922, 926 does not fill the channels 910, 912, 928, 930.

The first set of channels 910 are alternatively disposed in a radial direction relative to the second set of channels 912. The third set of channels 928 are alternatively disposed in a radial direction relative to the fourth set of channels 930. Although the channels 910 are shown vertically offset from the channels 912, the channels 910 may not be vertically offset from the channels 912. The channels 910 are vertically offset from the channels 912 to provide gaps radially between channels along a same cladding layer for brazing.

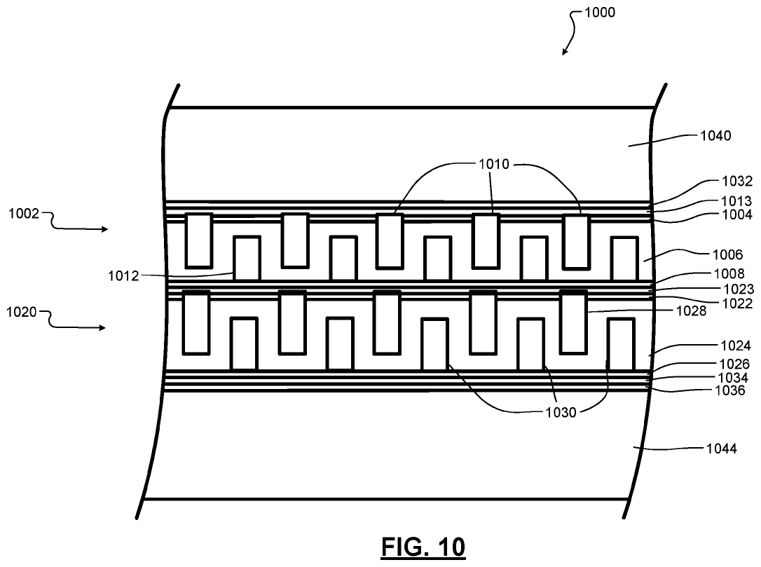

FIG. 10 shows a portion 1000 of a layered stack of a cooling assembly including cladding-metal-cladding stacks with offset channels. The cooling assembly includes a first cooling layer 1002 including a first cladding layer 1004, a first body layer 1006, a second cladding layer 1008, a first set of channels 1010 and a second set of channels 1012. The first set of channels 1010 extend vertically through the first cladding layer 1004 and contact a first core layer 1013 and extend vertically and partially into the first body layer 1006. The second set of channels 1012 are vertically offset from the first set of channels 1010, extend vertically and partially in the first body layer 1006 and contact the second cladding layer 1008. The first core layer 1013 is disposed on the first set of channels 1010 and the first body layer 1006.

The cooling assembly further includes a second cooling layer 1020 including a third cladding layer 1022, a second body layer 1024, a fourth cladding layer 1026, a third set of channels 1028 and a fourth set of channels 1030. The third set of channels 1028 extend through the third cladding layer 1022 and contact a second core layer 1023 and extend vertically and partially into the second body layer 1024. The fourth set of channels 1030 are vertically offset from the third set of channels 1028, extend vertically and partially into the second body layer 1024 and contact the fourth cladding layer 1026. The third set of channels 1028 may be radially aligned with the first set of channels 1010. The fourth set of channels 1030 may be radially aligned with the second set of channels 1012.

A fifth cladding layer 1032 may be disposed on the first core layer 1013. The second core layer 1023 may be disposed between the second cladding layer 1008 and the third cladding layer 1022. A third core layer 1034 may be disposed below the fourth cladding layer 1026. A sixth cladding layer 1036 may be disposed below the third core layer 1034.

The layers 1004, 1013, 1032 are disposed between body layers 1006, 1040. The layers 1026, 1034, 1036 are disposed between body layers 1024, 1044. In an embodiment, the body layers 1006, 1024, 1040, 1044 are implemented as metal layers. As an example, the cladding layers 1004, 1008, 1022, 1026, 1032, 1036 may be formed of aluminum cladding material, the core layers 1013, 1023, 1034 may be formed of an aluminum alloy, and the body layers 1006, 1024, 1040, 1044 may be formed of aluminum. In the example of FIG. 10, the channels 1010, 1012, 1028, 1030 are machined in the cladding layers 1004, 1022 and may be partially machined into one or more of the layers 1008, 1013, 1023, 1026. The core layers 1013, 1023, 1034 may be brazed to the body layers 1006, 1024, 1040, 1044 by melting the cladding layers 1004, 1008, 1022, 1026, 1032, 1036. The melting of the cladding layers 1004, 1008, 1022, 1026, 1032, 1036 does not fill the channels 1010, 1012, 1028, 1030.

The first set of channels 1010 are alternatively disposed in a radial direction relative to the second set of channels 1012. The third set of channels 1028 are alternatively disposed in a radial direction relative to the fourth set of channels 1030. Although the channels 1010 are shown vertically offset from the channels 1012, the channels 1010 may not be vertically offset from the channels 1012. The channels 1010 are vertically offset from the channels 1012 to provide gaps radially between channels along a same cladding layer for brazing.

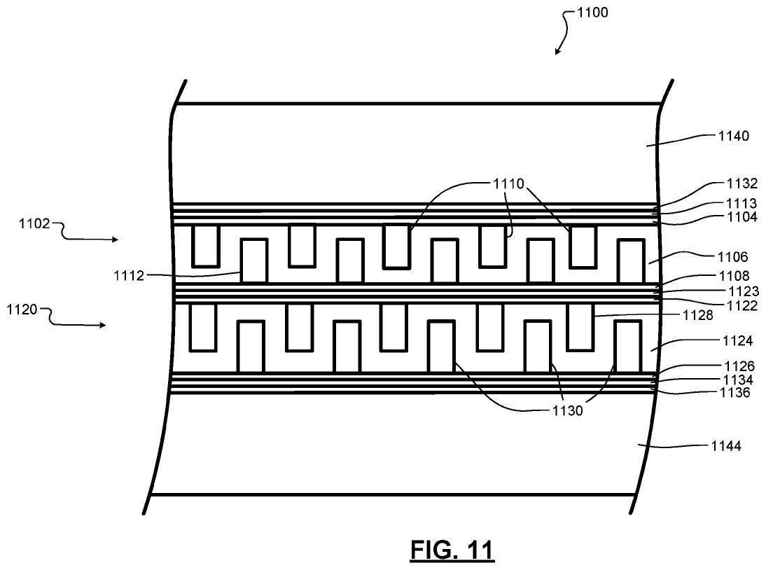

FIG. 11 shows a portion 1100 of a layered stack of a cooling assembly including body layers with offset channels. The cooling assembly includes a first cooling layer 1102 including a first cladding layer 1104, a first body layer 1106, a second cladding layer 1108, a first set of channels 1110 and a second set of channels 1112. The first set of channels 1110 contact the first cladding layer 1104 and extend vertically and partially into the first body layer 1106. The second set of channels 1112 are vertically offset from the first set of channels 1110, extend vertically and partially into the first body layer 1106 and contact the second cladding layer 1108. A first core layer 1113 is disposed on the first set of channels 1110 and the first body layer 1106.

The cooling assembly further includes a second cooling layer 1120 including a third cladding layer 1122, a second body layer 1124, a fourth cladding layer 1126, a third set of channels 1128 and a fourth set of channels 1130. The third set of channels 1128 contact the third cladding layer 1122 and extend vertically and partially into the second body layer 1124. The fourth set of channels 1130 are vertically offset from the third set of channels 1128, extend vertically and partially into the second body layer 1124 and contact the fourth cladding layer 1126. The third set of channels 1128 may be radially aligned with the first set of channels 1110. The fourth set of channels 1130 may be radially aligned with the second set of channels 1112.

A fifth cladding layer 1132 may be disposed on the first core layer 1113. The second core layer 1123 may be disposed between the second cladding layer 1108 and the third cladding layer 1122. A third core layer 1134 may be disposed below the fourth cladding layer 1126. A sixth cladding layer 1136 may be disposed below the third core layer 1134.

The layers 1104, 1113, 1132 are disposed between body layers 1106, 1140. The layers 1126, 1134, 1136 are disposed between body layers 1124, 1144. In an embodiment, the body layers 1106, 1124, 1140, 1144 are implemented as metal layers. As an example, the cladding layers 1104, 1108, 1122, 1126, 1132, 1136 may be formed of aluminum cladding material, the core layers 1113, 1123, 1134 may be formed of an aluminum alloy, and the body layers 1106, 1124, 1140, 1144 may be formed of aluminum. In the example of FIG. 11, the channels 1110, 1112, 1128, 1130 may be partially machined in the cladding layers 1104, 1108, 1122, 1126 and are partially machined into the body layers 1106, 1124. The core layers 1113, 1123, 1134 may be brazed to the body layers 1106, 1124, 1140, 1144 by melting the cladding layers 1104, 1108, 1122, 1126, 1132, 1136. The melting of the cladding layers 1104, 1108, 1122, 1126, 1132, 1136 does not fill the channels 1110, 1112, 1128, 1130.

The first set of channels 1110 are alternatively disposed in a radial direction relative to the second set of channels 1112. The third set of channels 1128 are alternatively disposed in a radial direction relative to the fourth set of channels 1130. Although the channels 1110 are shown vertically offset from the channels 1112, the channels 1110 may not be vertically offset from the channels 1112. The channels 1110 are vertically offset from the channels 1112 to provide gaps radially between channels along a same cladding layer for brazing.

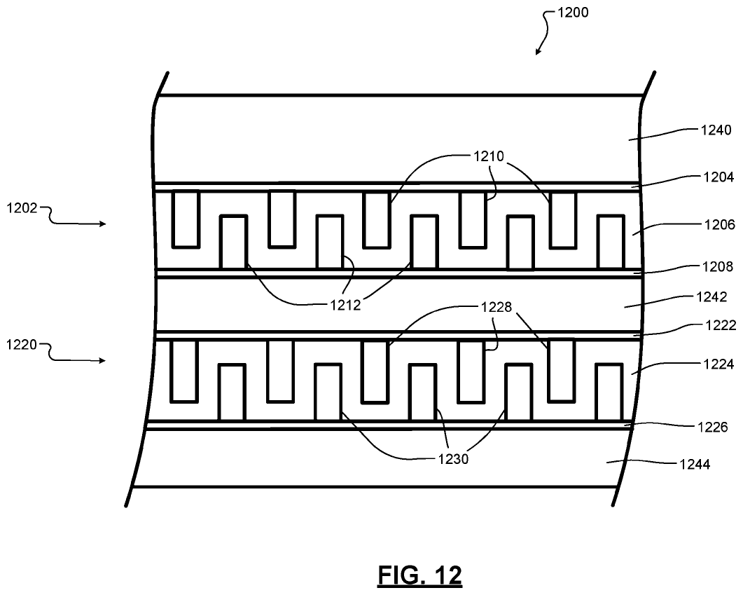

FIG. 12 shows a portion 1200 of a layered stack of a cooling assembly including metal-braze foil-metal stacks with offset channels. The cooling assembly includes a first cooling layer 1202 including a first braze foil layer 1204, a first body (or metal) layer 1206, a second braze foil layer 1208, a first set of channels 1210 and a second set of channels 1212. The first set of channels 1210 may contact the first braze foil layer 1204 and extend vertically and partially into the first body layer 1206. The second set of channels 1212 are vertically offset from the first set of channels 1210, may extend vertically and partially into the first body layer 1206, and contact the second braze foil layer 1208.

The cooling assembly further includes a second cooling layer 1220 including a third braze foil layer 1222, a second body layer 1224, a fourth braze foil layer 1226, a third set of channels 1228 and a fourth set of channels 1230. The third set of channels 1228 may contact the third braze foil layer 1222 and extend vertically and partially into the second body (or metal) layer 1224. The fourth set of channels 1230 are vertically offset from the third set of channels 1228, may extend vertically and partially into the second body layer 1224, and may contact the fourth sublayer layer 1226. The third set of channels 1228 may be radially aligned with the first set of channels 1210. The fourth set of channels 1230 may be radially aligned with the second set of channels 1212.

The layers 1204, 1206, 1208 are disposed between body layers 1240, 1242. The layers 1222, 1224, 1226 are disposed between body layers 1242, 1244. In an embodiment, the body layers 1206, 1224, 1240, 1242, 1244 are implemented as metal layers. As an example, the braze foil layers 1204, 1208, 1222, 1226 may be formed of aluminum material and the body layers 1206, 1224, 1240, 1242, 1244 may be formed of aluminum. In the example of FIG. 12, the channels 1210, 1212, 1228, 1230 may be partially machined in the braze foil layers 1204, 1208, 1222, 1226 and are machined partially into the body layers 1206, 1224. The body layers 1206, 1224 may be brazed to the body layers 1240, 1242, 1244 by melting the braze foil layers 1204, 1208, 1222, 1226. The melting of the braze foil layers 1204, 1208, 1222, 1226 does not fill the channels 1210, 1212, 1228, 1230.

The first set of channels 1210 are alternatively disposed in a radial direction relative to the second set of channels 1212. The third set of channels 1228 are alternatively disposed in a radial direction relative to the fourth set of channels 1230. Although the channels 1210 are shown vertically offset from the channels 1212, the channels 1210 may not be vertically offset from the channels 1212. The channels 1210 are vertically offset from the channels 1212 to provide gaps radially between channels along a same braze foil layer for brazing.

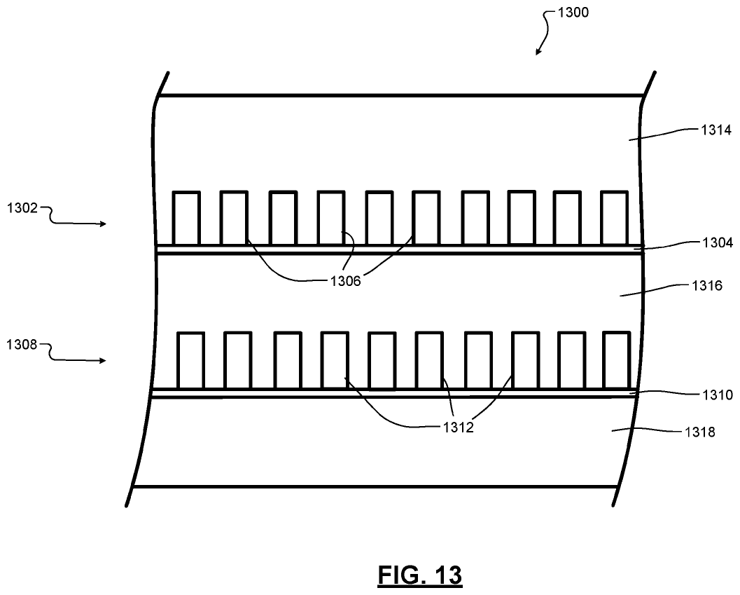

FIG. 13 shows a portion 1300 of a layered stack of a cooling assembly including non-offset channels and braze foil layers for brazing adjacent body layers. The cooling assembly includes i) a first cooling layer 1302 including a first braze foil layer 1304 and first set of channels 1306, and ii) a second cooling layer 1308 including a second braze foil layer 1310 and a second set of channels 1312. The first braze foil layer 1304 is disposed between body layers 1314, 1316. The second braze foil layer 1310 is disposed between body layers 1316, 1318. The body layers 1314, 1316 are brazed together by melting the first braze foil layer 1304. The body layers 1316, 1318 are brazed together by melting the second braze foil layer 1310. The first set of channels 1306 are not vertically offset from each other. The second set of channels 1312 are not vertically offset from each other.

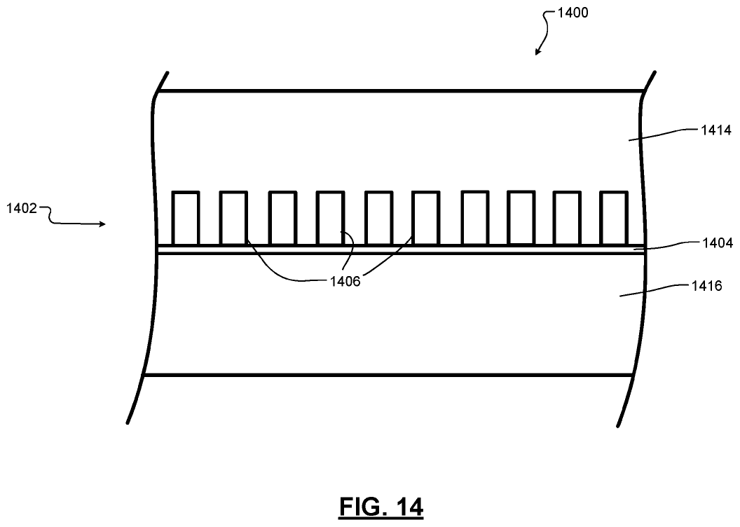

FIG. 14 shows a portion 1400 of a layered stack of a cooling assembly including a single layer of mesochannels and a braze foil layer for brazing adjacent body layers. The cooling assembly includes a cooling layer 1402 including a braze foil layer 1404 and a set of channels 1406. The braze foil layer 1404 is disposed between body layers 1414, 1416. The body layers 1414, 1416 are brazed together by melting the first braze foil layer 1404. The set of channels 1406 are not vertically offset from each other. As an example, the body layers 1404, 1406 may be copper plates, where at least one of the plates (e.g., the body layer 1414) is machined to have the set of the channels 1406.

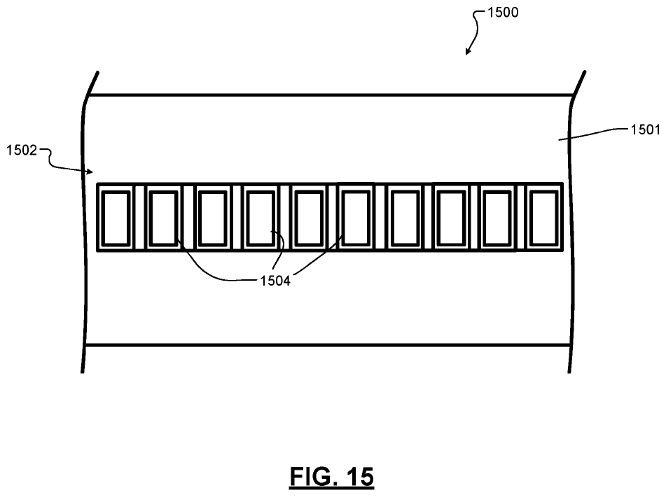

FIG. 15 shows a portion 1500 of a casting 1501 including an embedded mesochannel assembly (or insert) 1502 and embedded mesochannels 1504. A mesochannel assembly such as any of the mesochannel assemblies disclosed herein may be embedded in a casting (e.g., an aluminum casting). The mesochannels 1504 may be formed in the insert 1502. In an embodiment, the insert is formed of copper, Inconel (nickel-chromium-based superalloy), or other suitable material. In an embodiment, the insert is formed of copper, for example when a coolant such as water is to flow through the insert 1502. The casting 1501 is formed over the insert 1502. As an example, the insert 1502 may be formed using a 3D printing process. The casting 1501 being formed using a manufacturing process by which a liquid material is poured into a mold which includes the insert 1502, such that the casting 1501 is formed around the insert 1502.

The embodiments of FIGS. 14-15 can provide similar performance to a conventional alternative, but in a smaller volume with minimized weight and material cost.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A cold plate for a showerhead assembly, the cold plate comprising:
a body configured to be coupled to a showerhead of a substrate processing system;
a first cooling layer comprising a first plurality of spiral-shaped channels extending parallel to each other and azimuthally offset from each other;
a first supply manifold supplying coolant to each of the first plurality of spiral-shaped channels; and
a first return manifold receiving coolant from each of the first plurality of spiral-shaped channels,
wherein at least one of the first supply manifold and the first return manifold is circular shaped.

2. The cold plate of claim 1, further comprising:
a second cooling layer disposed below the first cooling layer and comprising a second plurality of spiral-shaped channels extending parallel to each other and azimuthally offset from each other;
a second supply manifold supplying coolant to each of the second plurality of spiral-shaped channels; and
a second return manifold receiving coolant from each of the second plurality of spiral-shaped channels,
wherein at least one of the second supply manifold and the second return manifold is circular shaped.

3. The cold plate of claim 2, further comprising:
a first one or more channels supply coolant to the first supply manifold and the second supply manifold; and
a second one or more channels receive coolant from the first return manifold and the second return manifold.

4. The cold plate of claim 1, wherein the first cooling layer comprises a second plurality of spiral-shaped channels extending parallel to each other and azimuthally offset from each other, the second plurality of spiral-shaped channels disposed separate from the first plurality of spiral-shaped channels.

5. The cold plate of claim 4, wherein the second plurality of spiral-shaped channels extend parallel to, are azimuthally and vertically offset from the first plurality of spiral-shaped channels, and extend from the first supply manifold to the first return manifold.

6. The cold plate of claim 4, further comprising:
a second supply manifold supplying coolant to each of the second plurality of spiral-shaped channels; and
a second return manifold receiving coolant from each of the second plurality of spiral-shaped channels,
wherein
at least one of the second supply manifold and the second return manifold is circular shaped; and
the second plurality of spiral-shaped channels are disposed radially outward of the first plurality of spiral-shaped channels.

7. The cold plate of claim 4, wherein the second plurality of spiral-shaped channels are wound about a same center axis as the first plurality of spiral-shaped channels.

8. The cold plate of claim 4, wherein the first cooling layer comprises a third plurality of spiral-shaped channels vertically offset from, extending parallel to, and in an alternating arrangement with the first plurality of spiral-shaped channels.

9. The cold plate of claim 8, wherein the second cooling layer comprises a fourth plurality of spiral-shaped channels vertically offset from, extending parallel to, and in an alternating arrangement with the second plurality of spiral-shaped channels.

10. The cold plate of claim 4, wherein:
the first cooling layer comprises a bore; and
some of the first plurality of spiral-shaped channels are wound at least one of toward and away from the bore and merge to form a first single channel, the first single channel disposed around a portion of the bore.

11. The cold plate of claim 10, wherein:
the bore extends through the second cooling layer;
some of the second plurality of spiral-shaped channels are wound at least one of toward and away from the bore and merge to form a second single channel; and
the second single channel is disposed around a portion of the bore.

12. The cold plate of claim 4, further comprising:
a second cooling layer disposed below the first cooling layer and comprising a third plurality of spiral-shaped channels extending parallel to each other and azimuthally offset from each other;
a third supply manifold supplying coolant to each of the third plurality of spiral-shaped channels; and
a third return manifold receiving coolant from each of the third plurality of spiral-shaped channels,
wherein at least one of the third supply manifold and the third return manifold is circular shaped.

13. The cold plate of claim 12, wherein the second cooling layer comprises:
a fourth plurality of spiral-shaped channels extending parallel to each other and azimuthally offset from each other, the fourth plurality of spiral-shaped channels disposed separate from the third plurality of spiral-shaped channels;
a fourth supply manifold supplying coolant to each of the fourth plurality of spiral-shaped channels; and
a fourth return manifold receiving coolant from each of the fourth plurality of spiral-shaped channels,
wherein at least one of the fourth supply manifold and the fourth return manifold is circular shaped.

14. The cold plate of claim 1, wherein:
the first cooling layer comprises a bore; and
some of the first plurality of spiral-shaped channels are wound at least one of toward and away from the bore and merge to form a first single channel, the first single channel disposed around a portion of the bore.

15. The cold plate of claim 1, wherein the first cooling layer comprises a second plurality of spiral-shaped channels vertically offset from, extending parallel to, and in an alternating arrangement with the first plurality of spiral-shaped channels.

16. The cold plate of claim 15, wherein the first cooling layer comprises:
a first cladding layer;
a second cladding layer disposed above the first cladding layer; and
a core layer disposed between the first cladding layer and the second cladding layer,
wherein
the first cladding layer bonds the core layer to a first body layer of the cold plate,
the second cladding layer bonds the core layer to a second body layer of the cold plate,
the first plurality of spiral-shaped channels are disposed in the first cladding layer and the core layer, and
the second plurality of spiral-shaped channels are disposed in the second cladding layer and the core layer.

17. The cold plate of claim 15, wherein the first cooling layer comprises:
a first cladding layer;
a second cladding layer disposed above the first cladding layer; and
a core layer disposed between the first cladding layer and the second cladding layer,
wherein
the first cladding layer bonds the core layer to a first body layer of the cold plate,
the second cladding layer bonds the core layer to a second body layer of the cold plate,
the first plurality of spiral-shaped channels are disposed in the first cladding layer, the core layer and the first body layer, and
the second plurality of spiral-shaped channels are disposed in the second cladding layer, the core layer and the second body layer.

18. The cold plate of claim 15, wherein the first cooling layer comprises:
a first cladding layer;
a second cladding layer disposed above the first cladding layer; and
a first body layer disposed between the first cladding layer and the second cladding layer,
wherein
the first cladding layer bonds the first body layer to a first core layer of the cold plate,
the second cladding layer bonds the first body layer to a second core layer of the cold plate,
the first plurality of spiral-shaped channels are disposed in the first cladding layer and the first body layer, and
the second plurality of spiral-shaped channels are disposed in the second cladding layer and a second body layer.

19. The cold plate of claim 18, wherein:
the first plurality of spiral-shaped channels are at least one of in contact with and partially disposed in the first core layer;
the first core layer is disposed on the first cladding layer;
the second plurality of spiral-shaped channels are at least one of in contact with and partially disposed in the second core layer; and
the second cladding layer is disposed on the second core layer.

20. The cold plate of claim 15, wherein the first cooling layer comprises:
a first cladding layer;
a second cladding layer disposed above the first cladding layer; and
a body layer disposed between the first cladding layer and the second cladding layer,
wherein
the first cladding layer bonds the body layer to a first core layer of the cold plate,
the second cladding layer bonds the body layer to a second core layer of the cold plate,
the first plurality of spiral-shaped channels are disposed in the body layer and are at least one of in contact with and disposed in the first cladding layer, and
the second plurality of spiral-shaped channels are disposed in the body layer and are at least one in contact with and disposed in the second cladding layer.

21. The cold plate of claim 15, wherein the first cooling layer comprises:
a first braze foil layer;
a second braze foil layer disposed above the first braze foil layer; and
a first body layer disposed between the first braze foil layer and the second braze foil layer,
wherein
the first braze foil layer bonds the first body layer to a second body layer of the cold plate,
the second braze foil layer bonds the first body layer to a third body layer of the cold plate,
the first plurality of spiral-shaped channels are disposed in the first body layer and are at least one of in contact with and disposed in the first braze foil layer, and
the second plurality of spiral-shaped channels are disposed in the second body layer and are at least one in contact with and disposed in the second braze foil layer.

22. The cold plate of claim 1, wherein the first cooling layer comprises:
a first body layer;
a second body layer disposed on the first body layer; and
a braze foil layer disposed between bonding the second body layer to the first body layer,
wherein the first plurality of spiral-shaped channels are disposed in the second body layer and are at least one of in contact with and disposed in the braze foil layer.

23. The cold plate of claim 22, wherein the first plurality of spiral-shaped channels are machined into the second body layer.

24. The cold plate of claim 1, wherein the first plurality of spiral-shaped channels are mesochannels and facilitate flow of coolant from the first supply manifold to the first return manifold.

25. The cold plate of claim 1, wherein the first cooling layer comprises:
a casting; and
an insert embedded in the casting and comprising the first plurality of spiral-shaped channels.

26. A substrate support comprising:
a body configured to support a substrate within a substrate processing system; and
a cooling assembly disposed in the body and comprising
a first cooling layer comprising a first plurality of spiral-shaped channels extending parallel to each other and azimuthally offset from each other,
a first supply manifold supplying coolant to each of the first plurality of spiral-shaped channels, and
a first return manifold receiving coolant from each of the first plurality of spiral-shaped channels,
wherein at least one of the first supply manifold and the first return manifold is circular shaped.

27. The substrate support of claim 26, wherein the cooling assembly further comprises:
a second cooling layer disposed below the first cooling layer and comprising a second plurality of spiral-shaped channels extending parallel to each other and azimuthally offset from each other;
a second supply manifold supplying coolant to each of the second plurality of spiral-shaped channels; and
a second return manifold receiving coolant from each of the second plurality of spiral-shaped channels,
wherein at least one of the second supply manifold and the second return manifold is circular shaped.

28. The substrate support of claim 27, further comprising:
a first one or more channels supply coolant to the first supply manifold and the second supply manifold; and
a second one or more channels receive coolant from the first return manifold and the second return manifold.

29. The substrate support of claim 26, wherein the first cooling layer comprises a second plurality of spiral-shaped channels extending parallel to each other and azimuthally offset from each other, the second plurality of spiral-shaped channels disposed separate from the first plurality of spiral-shaped channels.

30. The substrate support of claim 29, wherein the second plurality of spiral-shaped channels extend parallel to, are azimuthally and vertically offset from the first plurality of spiral-shaped channels, and extend from the first supply manifold to the first return manifold.

31. The substrate support of claim 29, further comprising:
a second supply manifold supplying coolant to each of the second plurality of spiral-shaped channels; and
a second return manifold receiving coolant from each of the second plurality of spiral-shaped channels,
wherein
at least one of the second supply manifold and the second return manifold is circular shaped; and
the second plurality of spiral-shaped channels are disposed radially outward of the first plurality of spiral-shaped channels.

32. The substrate support of claim 29, wherein the second plurality of spiral-shaped channels are wound about a same center axis as the first plurality of spiral-shaped channels.

33. The substrate support of claim 29, wherein the first cooling layer comprises a third plurality of spiral-shaped channels vertically offset from, extending parallel to, and in an alternating arrangement with the first plurality of spiral-shaped channels.

34. The substrate support of claim 33, wherein the second cooling layer comprises a fourth plurality of spiral-shaped channels vertically offset from, extending parallel to, and in an alternating arrangement with the second plurality of spiral-shaped channels.

35. The substrate support of claim 29, wherein:
the first cooling layer comprises a bore; and
some of the first plurality of spiral-shaped channels are wound at least one of toward and away from the bore and merge to form a first single channel, the first single channel disposed around a portion of the bore.

36. The substrate support of claim 35, wherein:
the bore extends through the second cooling layer;
some of the second plurality of spiral-shaped channels are wound at least one of toward and away from the bore and merge to form a second single channel; and
the second single channel disposed around a portion of the bore.

37. The substrate support of claim 29, further comprising:
a second cooling layer disposed below the first cooling layer and comprising a third plurality of spiral-shaped channels extending parallel to each other and azimuthally offset from each other;
a third supply manifold supplying coolant to each of the third plurality of spiral-shaped channels; and
a third return manifold receiving coolant from each of the third plurality of spiral-shaped channels,
wherein at least one of the third supply manifold and the third return manifold is circular shaped.

38. The substrate support of claim 37, wherein the second cooling layer comprises:
a fourth plurality of spiral-shaped channels extending parallel to each other and azimuthally offset from each other, the fourth plurality of spiral-shaped channels disposed separate from the third plurality of spiral-shaped channels;
a fourth supply manifold supplying coolant to each of the fourth plurality of spiral-shaped channels; and
a fourth return manifold receiving coolant from each of the fourth plurality of spiral-shaped channels,
wherein at least one of the fourth supply manifold and the fourth return manifold is circular shaped.

39. The substrate support of claim 26, wherein:
the first cooling layer comprises a bore; and
some of the first plurality of spiral-shaped channels are wound at least one of toward and away from the bore and merge to form a first single channel, the first single channel disposed around a portion of the bore.

40. The substrate support of claim 26, wherein the first cooling layer comprises a second plurality of spiral-shaped channels vertically offset from, extending parallel to, and in an alternating arrangement with the first plurality of spiral-shaped channels.

41. The substrate support of claim 40, wherein the first cooling layer comprises:
a first cladding layer;
a second cladding layer disposed above the first cladding layer; and
a core layer disposed between the first cladding layer and the second cladding layer,
wherein
the first cladding layer bonds the core layer to a first body layer of the substrate support,
the second cladding layer bonds the core layer to a second body layer of the substrate support,
the first plurality of spiral-shaped channels are disposed in the first cladding layer and the core layer, and
the second plurality of spiral-shaped channels are disposed in the second cladding layer and the core layer.

42. The substrate support of claim 40, wherein the first cooling layer comprises:
a first cladding layer;
a second cladding layer disposed above the first cladding layer; and
a core layer disposed between the first cladding layer and the second cladding layer,
wherein
the first cladding layer bonds the core layer to a first body layer of the substrate support,
the second cladding layer bonds the core layer to a second body layer of the substrate support,
the first plurality of spiral-shaped channels are disposed in the first cladding layer, the core layer and the first body layer, and
the second plurality of spiral-shaped channels are disposed in the second cladding layer, the core layer and the second body layer.

43. The substrate support of claim 40, wherein the first cooling layer comprises:
a first cladding layer;
a second cladding layer disposed above the first cladding layer; and
a first body layer disposed between the first cladding layer and the second cladding layer,
wherein
the first cladding layer bonds the first body layer to a first core layer of the substrate support,
the second cladding layer bonds the first body layer to a second core layer of the substrate support,
the first plurality of spiral-shaped channels are disposed in the first cladding layer and the first body layer, and
the second plurality of spiral-shaped channels are disposed in the second cladding layer and a second body layer.

44. The substrate support of claim 43, wherein:
the first plurality of spiral-shaped channels are at least one of in contact with and partially disposed in the first core layer;
the first core layer is disposed on the first cladding layer;
the second plurality of spiral-shaped channels are at least one of in contact with and partially disposed in the second core layer; and
the second cladding layer is disposed on the second core layer.

45. The substrate support of claim 40, wherein the first cooling layer comprises:
a first cladding layer;
a second cladding layer disposed above the first cladding layer; and
a body layer disposed between the first cladding layer and the second cladding layer,
wherein
the first cladding layer bonds the body layer to a first core layer of the substrate support,
the second cladding layer bonds the body layer to a second core layer of the substrate support,
the first plurality of spiral-shaped channels are disposed in the body layer and are at least one of in contact with and disposed in the first cladding layer, and
the second plurality of spiral-shaped channels are disposed in the body layer and are at least one in contact with and disposed in the second cladding layer.

46. The substrate support of claim 40, wherein the first cooling layer comprises:
a first braze foil layer;
a second braze foil layer disposed above the first braze foil layer; and
a first body layer disposed between the first braze foil layer and the second braze foil layer,
wherein
the first braze foil layer bonds the first body layer to a second body layer of the substrate support,
the second braze foil layer bonds the first body layer to a third body layer of the substrate support,
the first plurality of spiral-shaped channels are disposed in the first body layer and are at least one of in contact with and disposed in the first braze foil layer, and
the second plurality of spiral-shaped channels are disposed in the second body layer and are at least one in contact with and disposed in the second braze foil layer.

47. The substrate support of claim 26, wherein the first cooling layer comprises:
a first body layer;
a second body layer disposed on the first body layer; and
a braze foil layer disposed between bonding the second body layer to the first body layer,
wherein the first plurality of spiral-shaped channels are disposed in the second body layer and are at least one of in contact with and disposed in the braze foil layer.

48. The substrate support of claim 47, wherein the first plurality of spiral-shaped channels are machined into the second body layer.

49. The substrate support of claim 26, wherein the first plurality of spiral-shaped channels are mesochannels and facilitate flow of coolant from the first supply manifold to the first return manifold.

50. The substrate support of claim 26, wherein the first cooling layer comprises:
a casting; and
an insert embedded in the casting and comprising the first plurality of spiral-shaped channels.
